(19) United States
(12) Patent Application Publication
(10) Pub. No.: US 2025/0113709 A1
(43) Pub. Date: Apr. 3, 2025

(54) DISPLAY DEVICE

(71) Applicant: Japan Display Inc., Tokyo (JP)

(72) Inventors: Hajime WATAKABE, Tokyo (JP); Masashi TSUBUKU, Tokyo (JP); Kentaro MIURA, Tokyo (JP); Masahiro WATABE, Tokyo (JP)

(73) Assignee: Japan Display Inc., Tokyo (JP)

(21) Appl. No.: 18/895,446

(22) Filed: Sep. 25, 2024

(30) Foreign Application Priority Data
Sep. 29, 2023 (JP) 2023-170260

(51) Int. Cl. H10K 59/124; H01L 27/12; H10K 59/121; H10K 59/131

(52) U.S. Cl. CPC H10K 59/124; H10D 86/423; H10D 86/60; H10K 59/1213; H10K 59/131

(57) ABSTRACT

A display device includes a light-emitting element, a first transistor, and a second transistor, the first transistor includes a first gate electrode, a first insulating film, a first oxide semiconductor layer, a second insulating film, and a first conductive layer provided on the second insulating film, and the second transistor includes the first insulating film, a second oxide semiconductor layer, a second insulating film, and a second gate electrode, wherein an etching rate of the first oxide semiconductor layer and the second semiconductor layer is less than 3 nm/min when the first oxide semiconductor layer and the second semiconductor layer are etched using an etching solution containing phosphoric acid as a main component at 40° C.

### CROSS-REFERENCE TO RELATED APPLICATION

This application claims the benefit of priority to Japanese Patent Application No. 2023-170260, filed on Sep. 29, 2023, the entire contents of which are incorporated herein by reference.

### FIELD

An embodiment of the present invention relates to a semiconductor device in which an oxide semiconductor is used as a channel. In addition, an embodiment of the present invention relates to a display device to which the semiconductor device is applied.

### BACKGROUND

In recent years, a semiconductor device in which an oxide semiconductor is used for a channel instead of amorphous silicon, low-temperature polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device in which the oxide semiconductor is used for the channel can be formed with a simple structure and a low-temperature process, similar to a semiconductor device in which amorphous silicon is used as a channel. The semiconductor device in which the oxide semiconductor is used for the channel is known to have higher mobility than the semiconductor device in which amorphous silicon is used for the channel.

In addition, use of an oxide semiconductor as a semiconductor layer that composes an OLED display is attracting attention. A transistor using the oxide semiconductor layer is expected to be applied to a low-power display device because of low off-leakage current and low-frequency driving. In particular, power consumption is greatly reduced by applying a transistor using the oxide semiconductor layer to a self-luminous organic EL display device.

### SUMMARY

A display device according to an embodiment of the present invention includes a light-emitting element, a first transistor controlling a current value flowing from a driving power supply line to the light-emitting element, and a second transistor applying a voltage corresponding to a luminance of the light-emitting element to a first gate electrode of the first transistor, wherein the first transistor includes the first gate electrode, a first insulating film provided on the first gate electrode, a first oxide semiconductor layer provided on the first insulating film and having a region overlapping the first gate electrode, a second insulating film provided on the first oxide semiconductor layer, and a first conductive layer provided on the second insulating film, the second transistor includes the first insulating film, a second oxide semiconductor layer provided on the first insulating film, a second insulating film arranged on the first oxide semiconductor layer and the second oxide semiconductor layer and having a thickness smaller than a thickness of the first insulating film, and a second gate electrode arranged on the second insulating film and having a region overlapping the second oxide semiconductor layer, wherein the first oxide semiconductor layer has a first channel region and a first high concentration impurity region sandwiching the first channel region, the second semiconductor layer has a second channel region and a second high concentration impurity region sandwiching the second channel region, the first conductive layer is electrically connected to the light emitting element, and an etching rate of the first oxide semiconductor layer and the second semiconductor layer is less than 3 nm/min when the first oxide semiconductor layer and the second semiconductor layer are etched using an etching solution containing phosphoric acid as a main component at 40° C.

A display device according to an embodiment of the present invention includes a light-emitting element, a first transistor controlling a current value flowing from a driving power supply line to the light-emitting element, and a second transistor applying a voltage corresponding to a luminance of the light-emitting element to a first gate electrode of the first transistor, wherein the first transistor includes the first gate electrode, a first insulating film provided on the first gate electrode, and a first oxide semiconductor layer provided on the first insulating film and having a region overlapping the first gate electrode, the second transistor includes the first insulating film, a second oxide semiconductor layer provided on the first insulating film, a second insulating film arranged on the first oxide semiconductor layer and the second oxide semiconductor layer and having a thickness smaller than a thickness of the first insulating film, and a second gate electrode arranged on the second insulating film and having a region overlapping the second oxide semiconductor layer, wherein the first oxide semiconductor layer has a first channel region, a low concentration impurity region sandwiching the first channel region, and a first high concentration impurity region adjacent to the low concentration impurity region, the second semiconductor layer has a second channel region and a second high concentration impurity region sandwiching the second channel region, and an etching rate of the first oxide semiconductor layer and the second semiconductor layer is less than 3 nm/min when the first oxide semiconductor layer and the second semiconductor layer are etched using an etching solution containing phosphoric acid as a main component at 40° C.

### BRIEF DESCRIPTION OF DRAWINGS

FIG. 1 is a plan view illustrating a configuration of a display device according to an embodiment of the present invention.

FIG. 2 is an equivalent circuit diagram of a pixel included in a display device according to an embodiment of the present invention.

FIG. 3 is a diagram illustrating a cross-sectional structure of a pixel of a display device according to an embodiment of the present invention.

FIG. 4 is a cross-sectional view illustrating a manufacturing method of a display device according to an embodiment of the present invention.

FIG. 5 is a cross-sectional view illustrating a manufacturing method of a display device according to an embodiment of the present invention.

FIG. 6 is a cross-sectional view illustrating a manufacturing method of a display device according to an embodiment of the present invention.

FIG. 7 is a cross-sectional view illustrating a manufacturing method of a display device according to an embodiment of the present invention.

FIG. 8 is a cross-sectional view illustrating a manufacturing method of a display device according to an embodiment of the present invention.

FIG. 9 is a cross-sectional view illustrating a manufacturing method of a display device according to an embodiment of the present invention.

FIG. 10 is a cross-sectional view illustrating a manufacturing method of a display device according to an embodiment of the present invention.

FIG. 11 is a cross-sectional view illustrating a manufacturing method of a display device according to an embodiment of the present invention.

FIG. 12 is a cross-sectional view illustrating a manufacturing method of a display device according to an embodiment of the present invention.

FIG. 13 is a diagram illustrating a cross-sectional structure of a pixel of a display device according to an embodiment of the present invention.

FIG. 14 is an equivalent circuit diagram of a pixel included in a display device according to an embodiment of the present invention.

FIG. 15 is a diagram illustrating a cross-sectional structure of a pixel of a display device according to an embodiment of the present invention.

FIG. 16 is a cross-sectional view illustrating a manufacturing method of a display device according to an embodiment of the present invention.

FIG. 17 is a cross-sectional view illustrating a manufacturing method of a display device according to an embodiment of the present invention.

FIG. 18 is a cross-sectional view illustrating a manufacturing method of a display device according to an embodiment of the present invention.

FIG. 19 is a diagram illustrating a cross-sectional structure of a pixel of a display device according to an embodiment of the present invention.

FIG. 20 is a diagram illustrating a cross-sectional structure of a pixel of a display device according to an embodiment of the present invention.

FIG. 21 is a cross-sectional view illustrating a manufacturing method of a display device according to an embodiment of the present invention.

FIG. 22 is a cross-sectional view illustrating a manufacturing method of a display device according to an embodiment of the present invention.

FIG. 23 is a diagram illustrating a cross-sectional structure of a pixel of a display device according to an embodiment of the present invention.

FIG. 24 is an equivalent circuit diagram of a pixel included in a display device according to an embodiment of the present invention.

FIG. 25 is a timing chart of a pixel circuit shown in FIG. 24.

FIG. 26 is an equivalent circuit diagram of a pixel included in a display device according to an embodiment of the present invention.

FIG. 27 is a timing chart of a pixel circuit shown in FIG. 26.

### DESCRIPTION OF EMBODIMENTS

A transistor using an oxide semiconductor layer has a problem of low reliability, such as a change in threshold voltage over time. In the case where the transistor using the oxide semiconductor layer is formed in a bottom gate structure or a dual gate structure, it is difficult to ensure sufficient reliability.

An object of an embodiment of the present invention is to improve the reliability of a display device.

Hereinafter, embodiments of the present invention will be described with reference to the drawings and the like. However, the present invention can be implemented in various forms without departing from the gist of the present invention, and is not to be construed as being limited to the description of the embodiments illustrated below. In addition, in order to make the description clearer with respect to the drawings, the width W, thickness, shape, and the like of each part may be schematically represented in comparison with actual embodiments, but the schematic drawings are merely examples, and do not limit the interpretation of the present invention. Further, in the present specification and the drawings, the same or similar elements as those described with respect to the above-described drawings are denoted by the same reference signs, and redundant description may be omitted.

In the present specification, in the case where a single film is processed to form a plurality of films, the plurality of films may have different functions and roles. However, the plurality of films is derived from films formed as the same layer in the same process, and has the same layer structure and the same material. Therefore, the plurality of films is defined as being present in the same layer.

Further, in the present specification, expressions such as “above” and “below” in describing the drawings represent relative positional relationships between a structure of interest and another structure. In the present specification, in a side view, a direction from a first substrate to a pixel electrode, which will be described later, is defined as “above”, and a reverse direction thereof is defined as “below”. In this specification and claims, the expression “on” in describing the manner of arranging another structure on a certain structure shall include both arranging another structure directly above a certain structure and arranging another structure over a certain structure via yet another structure, unless otherwise specified.

### First Embodiment

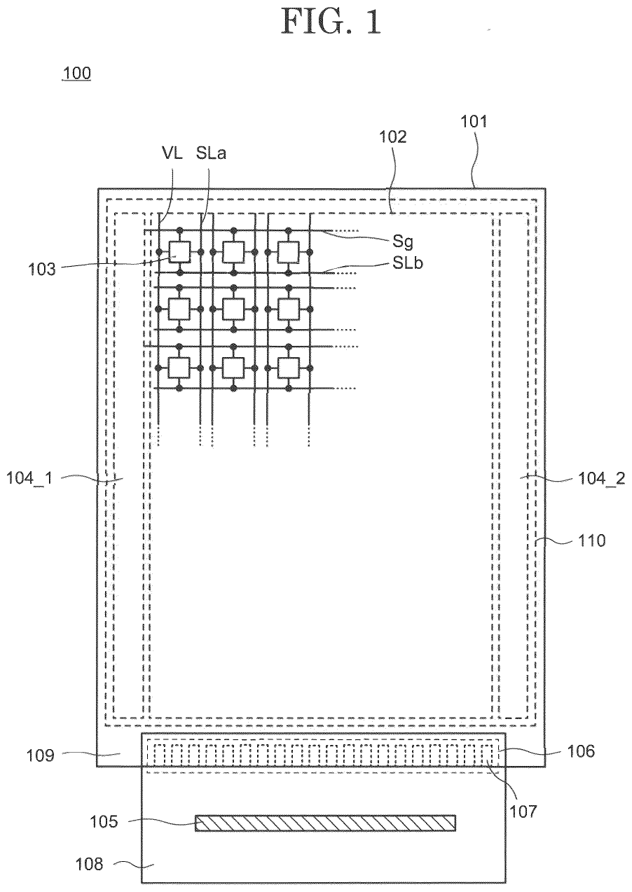

A display device 100 according to an embodiment of the present invention will be described with reference to FIG. 1 to FIG. 12.

FIG. 1 is a plan view illustrating a configuration of a display device 100 according to an embodiment of the present invention. As shown in FIG. 1, the display device 100 includes a display region 102 and a peripheral region 109 arranged on a substrate 101.

The display region 102 includes a plurality of pixels 103 arranged in a matrix. Each of the plurality of pixels 103 includes a plurality of transistors and light-emitting elements.

The peripheral region 109 is arranged to surround the display region 102. The peripheral region 109 in the substrate 101 refers to a region from the display region 102 to an end portion of the substrate 101. In other words, the peripheral region 109 refers to the substrate 101 that is not arranged with the display region 102 (i.e., a region outside the display region 102). The peripheral region 109 includes gate driving circuits 104_1 and 104_2, and a terminal portion 106 including a plurality of terminals 107. The gate driving circuits 104_1 and 104_2 are arranged so as to sandwich the display region 102. The plurality of terminals 107 is connected to a flexible printed circuit 108. In FIG. 1, although an example is shown in which the driver IC 105 includes a source driving circuit, the example is not limited to this structure, and a source driving circuit may be arranged separately from the driver IC 105 on the substrate 101. In addition, although an example in which the driver IC 105 is arranged in the flexible printed circuit 108 is shown, the driver IC 105 may be arranged in the substrate 101 in the form of an IC chip.

The driver IC 105 is connected to the gate driving circuits 104_1 and 104_2 and a plurality of video signal lines VL. The gate driving circuit 104_1 or the gate driving circuit 104_2 is connected to the pixel 103 via a write control scanning line Sg. Among the plurality of write control scanning lines Sg, for example, the write control scanning line Sg in an odd-numbered row is connected to the gate driving circuit 104_1, and the write control scanning line Sg in an even-numbered row is connected to the gate driving circuit 104_2. The video signal line VL is connected to the pixel 103. A control signal SG for selecting each pixel 103 is applied to the display region 102 from the driver IC 105 via the gate driving circuits 104_1 and 104_2 and the write control scanning line Sg. In addition, a video signal Vsig is applied to the display region 102 from the driver IC 105 via the video signal line VL. With these signals, the transistors included in the pixel 103 can be driven, and an image corresponding to the video signal Vsig can be displayed on the display region 102. In addition, each of a high potential power source line SLa and a low potential power source electrode SLb connected to the pixel 103 is connected to different terminals 107.

A glass substrate or a flexible plastic substrate is used as the substrate 101. If a flexible plastic substrate is used as the substrate 101, a region between the display region 102 and the terminal portion 106 can be folded. This makes it possible to reduce the frame size of the display device 100.

### [Equivalent Circuit Diagram]

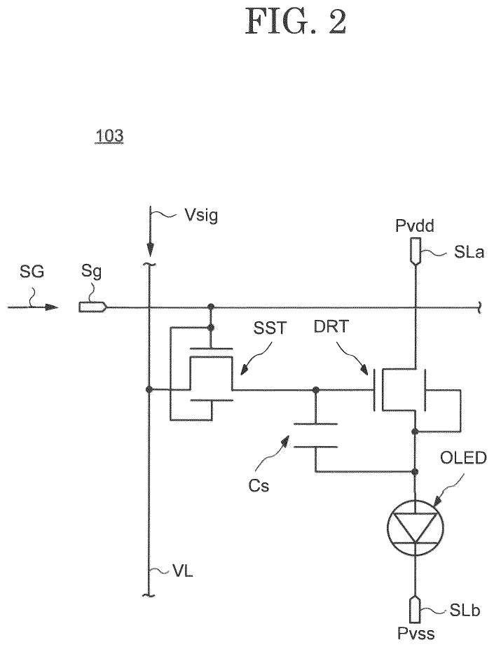

FIG. 2 is an equivalent circuit diagram of the pixel 103 included in the display device 100 according to an embodiment of the present invention. The display device 100 has the high potential power source line SLa, the low potential power source electrode SLb, the write control scanning line Sg, and the video signal line VL. A high potential power source Pvdd is applied to the high potential power source line SLa, and a low potential power source Pvss is applied to the low potential power source electrode SLb. The write control scanning line Sg is connected to the gate driving circuits 104_1 and 104_2, and the video signal line VL is connected to the driver IC 105.

Each pixel 103 includes at least a driving transistor DRT, a writing transistor SST, and a light-emitting element OLED. The high potential power source Pvdd is applied to an anode (also referred to as a pixel electrode) of the light-emitting element OLED and a low potential power source Pvss is applied to the cathode (also referred to as a common electrode) via the driving transistor DRT. The driving transistor DRT is connected in series with the light-emitting element OLED between the high potential power source line SLa and the low potential power source electrode SLb. The driving transistor DRT functions as a current control element that controls a current flowing through the light-emitting element OLED according to a gate-source voltage. The writing transistor SST functions as a switching element that selects conduction or non-conduction between two nodes, and writes a voltage corresponding to the emission luminance of the light-emitting element OLED. A holding capacity Cs may be arranged between the gate-source of the driving transistor DRT. The holding capacity Cs holds the gate-source voltage of the driving transistor DRT for a certain period.

The writing transistor SST includes a first terminal, a second terminal, and a control terminal. The driving transistor DRT includes a first terminal, a second terminal, a first control terminal, and a second control terminal. In the present embodiment, the first terminal is referred to as a source electrode, the second terminal is referred to as a drain electrode, the first control terminal is referred to as a first gate electrode, and the second control terminal is referred to as a second gate electrode.

In the writing transistor SST, the first gate electrode and the second gate electrode are connected to the write control scanning line Sg, the source electrode is connected to the video signal line VL, and the drain electrode is connected to the first gate electrode of the driving transistor DRT. In the driving transistor DRT, the drain electrode is connected to the high potential power source line SLa, and the source electrode is connected to one of the electrodes (in this case, the anode) of the second gate electrode and the light-emitting element OLED. The other electrode (in this case, the cathode) of the light-emitting element OLED is connected to the low potential power source electrode SLb. The driving transistor DRT outputs a driving current with a current amount corresponding to the video signal Vsig to the light-emitting element OLED.

For example, amorphous silicon, low-temperature polysilicon, or an oxide semiconductor is used as the semiconductor layer of the transistor constituting the display device 100. In this case, since the transistor using the oxide semiconductor layer has a low off-leakage current and can be driven at a low frequency, the display device 100 with low power consumption can be realized. In addition, the transistor using the oxide semiconductor layer has better saturating properties than a transistor including a low-temperature polysilicon layer because the kink effect is not observed. In the present embodiment, the case where the oxide semiconductor layer is used as the semiconductor layer of the transistor constituting the display device 100 will be described.

A transistor using the oxide semiconductor layer has a problem of low reliability, such as a change in threshold voltage over time. For example, in the case where the writing transistor and the driving transistor are formed with a dual gate structure to increase an ON current of the transistor using the oxide semiconductor layer, a voltage applied to the oxide semiconductor layer is likely to be applied to the driving transistor, and a large amount of current flows through the driving transistor. As a result, thermal degradation occurs in the oxide semiconductor layer, and the reliability of the driving transistor is reduced.

In the case where the transistor using the oxide semiconductor layer is formed with a top gate structure, forming a thickness of the gate insulating film to be 100 nm or more and 200 nm or less makes it possible to increase the ON current and a sub-threshold swing value (hereinafter, referred to as “S value”) can be reduced. Therefore, in the case where the transistor with the top gate structure is used as the writing transistor, an effect can be obtained whereby a switching characteristic is improved due to a small S value. On the other hand, in the case where the transistor with the top gate structure is used as the driving transistor, the transistor is current driven, and the small S value causes a large current change. In particular, in a low gradation region that needs to be controlled with a small current, the change in the current of the driving transistor becomes large even if the gate voltage is slightly changed, so that it becomes impossible to finely control the gradation. As a result, display unevenness is likely to occur in the display region 102.

In addition, in the case where the transistor using the oxide semiconductor layer is formed with the bottom gate structure, since the thickness of the gate insulating film is made to be thicker, it is difficult to apply a voltage applied to the oxide semiconductor layer, so that an amount of current flowing through the transistor can be reduced. Therefore, in the case where the transistor with the bottom gate structure having a thick gate insulating film is used as the driving transistor, thermal degradation to the oxide semiconductor layers is suppressed, and the reliability of the transistor is improved. On the other hand, in the case where the transistor with the bottom gate structure having a thick gate insulating film is used as the writing transistor, an ON current Ion of the writing transistor tends to decrease due to the thick gate insulating film.

Therefore, in the case where the transistor using the oxide semiconductor layer is applied to a display device, it is preferred to arrange a transistor having various properties and structures depending on the required function. For example, a transistor having good switching characteristics and high ON current is preferably arranged in the writing transistor, and a transistor having lower switching characteristics than that of the writing transistor and suppressed thermal deterioration and high reliability is preferably arranged in the driving transistor.

Therefore, in the display device 100 according to an embodiment of the present invention, the writing transistor SST having a switching function and the transistor constituting the gate driving circuits 104_1 and 104_2 are the top gate drive or dual gate drive, and the driving transistor having a current control function is the bottom gate drive. In addition, in the present specification and the like, the top gate drive is such that on/off is controlled by the gate electrode arranged above the oxide semiconductor layer. The top gate driving transistor may be a top gate structure formed of the gate electrode arranged above the oxide semiconductor layer or a dual gate structure formed of the gate electrode arranged above and below the oxide semiconductor layer. In addition, in this specification and the like, the bottom gate drive is such that on/off is controlled by the gate electrode arranged below the oxide semiconductor layer. As a bottom-gate drive transistor, a bottom-gate structure including a gate electrode located below the oxide semiconductor layer, or a dual-gate structure including a gate electrode located above and below the oxide semiconductor layer are possible, respectively. In addition, in the present specification, the dual gate drive is such that on/off is controlled by inputting the same control signal to the gate electrodes arranged above and below the oxide semiconductor layer.

### [Cross-Sectional Structure of Pixel]

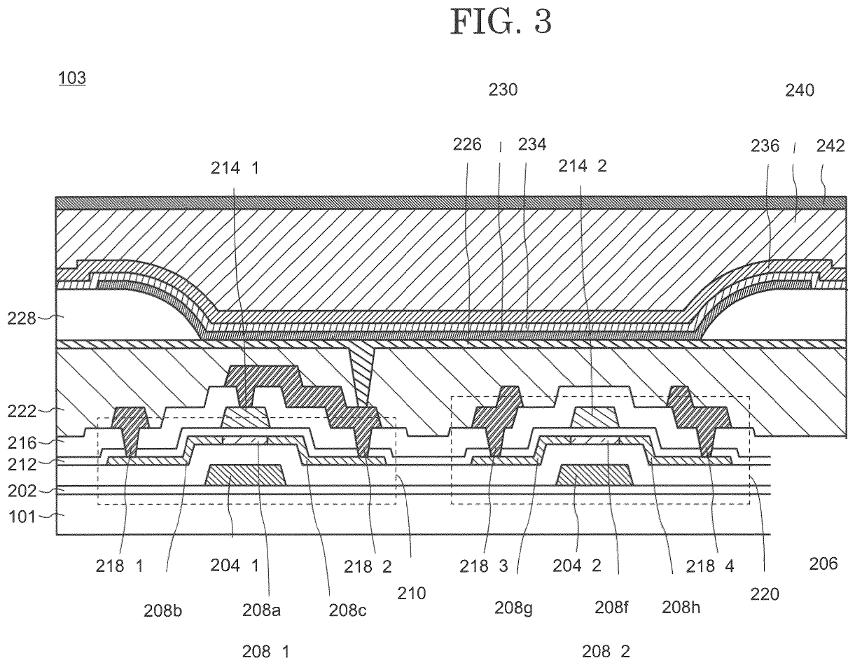

FIG. 3 is a diagram illustrating a cross-sectional structure of the pixel 103 of the display device 100 according to an embodiment of the present invention. As shown in FIG. 3, a transistor 210 and a transistor 220 are arranged on the substrate 101 via a base film 202. The transistor 210 is connected to a light-emitting element 230. In this case, the transistor 210 corresponds to the driving transistor DRT, the transistor 220 corresponds to the writing transistor SST, and the light-emitting element 230 corresponds to the light-emitting element OLED.

The transistor 210 functioning as the driving transistor DRT has a dual gate structure. The transistor 210 includes at least a conductive layer 204_1, an insulating film 206 arranged on the conductive layer 204_1, an oxide semiconductor layer 208_1 arranged on the insulating film 206, an insulating film 212 arranged on the oxide semiconductor layer 208_1, and a conductive layer 214_1 arranged on the insulating film 212. In this case, the first control terminal for controlling switching of the transistor 210 is the conductive layer 204_1. Therefore, the transistor 210 is the bottom gate drive. In addition, the conductive layer 204_1 also functions as a light-shielding layer for preventing a back surface of the oxide semiconductor layer 208 from being irradiated with light. The second control terminal is the conductive layer 214_2. In this case, the oxide semiconductor layer 208_1 includes a channel region 208a and high concentration impurity regions 208b and 208c. The high concentration impurity regions 208b and 208c are arranged with the channel region 208a interposed therebetween. In this case, the channel region 208a overlaps the conductive layer 204_1. The insulating film 206 functions as a gate insulating film of the transistor 210.

The channel region 208a has semi-conductive properties. Therefore, when a voltage is applied to the conductive layer 204_1, a channel that serves as a current path is formed in the channel region 208a. Each of the high concentration impurity region 208b and the high concentration impurity region 208c has conductive properties due to the addition of an impurity element. Therefore, a carrier concentration of the high concentration impurity region 208b and the high concentration impurity region 208c is greater than that of the channel region 208a. In other words, the channel region 208a has a higher electrical resistivity (or lower electrical conductivity) than each of the high concentration impurity region 208b and the high concentration impurity region 208c. When impurity elements are added to the oxide semiconductor layers 208_1 and 208_2 at a concentration of 1×10¹⁸ cm⁻³ or more and 1×10²¹ cm⁻³ or less as measured by SIMS analysis, a sheet resistance can be reduced. For example, the sheet resistance of the high concentration impurity region 208B and the high concentration impurity region 208C are 1000 Ω/sq. or less, preferably 500 Ω/sq or less, and more preferably 250 Ω/sq or less. Hereinafter, for convenience of explanation, a region such as the channel region 208a that has a higher electrical resistivity than the high concentration impurity region 208b and the high concentration impurity region 208c is referred to as a “high resistivity region.”

An insulating film 216 is arranged on the oxide semiconductor layer 208_1. The insulating film 216 functions as an interlayer insulating film. A source electrode and a drain electrode 218_1 and 218_2 are arranged on the insulating film 216. The source electrode or drain electrode 218_1 is connected to the high concentration impurity region 208b via a contact hole arranged in the insulating films 212 and 216. The source electrode or drain electrode 218_2 is connected to the high concentration impurity region 208c and the conductive layer 214_1. The conductive layer 214_1 is connected to a pixel electrode 226 of the light-emitting element OLED via the source electrode or drain electrode 218_2. Although not shown, the conductive layer 204_1 is electrically connected to one of a source electrode or drain electrode 218_3 and 218_4. The conductive layer 214_1 may be connected to a fixed potential in addition to the embodiment shown in FIG. 3. Examples of the fixed potential include the high potential power source Pvdd which is a driving power source of the light-emitting element OLED, or the low potential power source Pvss, and the like.

The transistor 220 functioning as the writing transistor SST is a dual gate structure. The transistor 220 includes at least a conductive layer 204_2, the insulating film 206 arranged on the conductive layer 204_2, an oxide semiconductor layer 208_2 arranged on the insulating film 206, the insulating film 212 arranged on the oxide semiconductor layer 208_2, and a conductive layer 214_2 arranged on the insulating film 212. In this case, the first control terminal for controlling switching of the transistor 220 is the conductive layer 204_2 and the conductive layer 214_2. Therefore, the transistor 220 is the dual gate drive. In addition, the conductive layer 204_1 also functions as a light-shielding layer for preventing a back surface of the oxide semiconductor layer 208 from being irradiated with light. The insulating film 206 and the insulating film 212 function as the gate insulating films. The oxide semiconductor layer 208_2 has a channel region 208f and high concentration impurity regions 208g and 208h. The high concentration impurity regions 208g and 208h are arranged with the channel region 208f interposed therebetween. In this case, the channel region 208f overlaps the conductive layer 214_2.

The channel region 208f has semi-conductive properties. Therefore, when a voltage is applied to the conductive layer 204_2 and the conductive layer 214_2, a channel that serves as a current path is formed in the channel region 208f. Each of the high concentration impurity region 208g and the high concentration impurity region 208h has conductive properties. Therefore, a carrier concentration of the high concentration impurity region 208g and the high concentration impurity region 208h is greater than that of the channel region 208f. In other words, the channel region 208f has a higher electrical resistivity (or lower electrical conductivity) than each of the high concentration impurity region 208g and the high concentration impurity region 208h. For example, the sheet resistance of the high concentration impurity region 208g and the high concentration impurity region 208h are 1000 Ω/sq. or less, preferably 500 Ω/sq. or less, and more preferably 250 Ω/sq. or less. The channel region 208f is also referred to a high-resistance region.

The insulating film 216 is arranged on the conductive layer 214_2. The source electrode and the drain electrode 218_3 and 218_4 are arranged on the insulating film 216. The source electrode and the drain electrode 218_3 and 218_4 are connected to the high concentration impurity regions 208g and 208h via the contact holes arranged in the insulating films 212 and 216.

In the present embodiment, a dual-gate driving transistor having a dual gate structure is arranged as the writing transistor SST and a dual-gate driving transistor having a bottom gate driving transistor is arranged as the driving transistor DRT on the same substrate in the display device 100. In this case, among the insulating films 206 and 212 vertically sandwiching the oxide semiconductor layers 208_1 and 208_2, both the insulating film 212 and the insulating film 206 are made to function as the gate insulating film in the writing transistor SST, and the insulating film 206 is made to function as the gate insulating film in the driving transistor DRT. The thickness of the insulating film 212 is smaller than the thickness of the insulating film 206. Therefore, the thicknesses of the gate insulating films can be made different between the writing transistor SST and the driving transistor DRT. Although the writing transistor SST is configured as a dual gate drive, a threshold voltage is dominated by the voltage applied by the conductive layer 214_2 arranged via the thin insulating film 212.

Since the gate insulating film of the writing transistor SST can be made thinner than the gate insulating film of the driving transistor DRT, an electric field is easily applied to the oxide semiconductor layer 208_2, and the ON current can be increased. In addition, in the writing transistor SST and the driving transistor DRT, since an impurity element is added to the oxide semiconductor layer 208_2 using the conductive layer 214_1 and 214_2 as a mask, a channel length L can be shortened. In an embodiment of the present invention, the writing transistor SST and the driving transistor DRT may have a channel length L of, for example, 2.0 μm or more and 4.0 μm or less. As a result, the S value of the writing transistor SST can be reduced, so that the switching characteristics of the writing transistor SST are improved. On the other hand, since the gate insulating film of the driving transistor DRT can be made thicker than the gate insulating film of the writing transistor SST, an electric field is less likely to be applied to the oxide semiconductor layer 208_1, and the ON current of the driving transistor DRT can be reduced. In addition, since the S value of the driving transistor DRT can be increased, the current change can be reduced in the low gradation region controlled by the small current, and the gradation can be finely controlled. As a result, it is possible to suppress the occurrence of display unevenness in the display region 102. Further, since a large amount of current can be suppressed from flowing through the driving transistor DRT, it is possible to suppress a decrease in reliability due to thermal degradation.

In the driving transistor DRT, the conductive layer 214_1 and the high concentration impurity region 208c are connected via the source electrode or drain electrode 218_2. The conductive layer 214_1 is connected to the pixel electrode 226 of the light-emitting element OLED via the source electrode or drain electrode 218_2. This makes it possible to stabilize the driving transistor DRT. Therefore, it is possible to suppress the occurrence of display unevenness in the display region 102.

Furthermore, the gate driving circuits 104_1 and 104_2 can be driven at high speed by applying the transistor 220 having the same structure as the writing transistor SST to the transistor constituting the gate driving circuits 104_1 and 104_2.

A flattening film 222 is arranged on the source electrodes or drain electrodes 218_1 to 218_4. An organic resin material such as polyimide, polyamide, acryl, or epoxy can be used as the flattening film 222. These materials can be formed into films by a solution coating method and have a high flattening effect. In addition, the flattening film 222 is not arranged in the peripheral region 109.

The transistor 210 is connected to the light-emitting element 230. The light-emitting element 230 has the pixel electrode 226, an organic layer 232, and a common electrode 234. In an embodiment of the present invention, the display device 100 may be a top-emission type or a bottom-emission type. In the present embodiment, the display device 100 is a top-emission structure. In the top-emission structure, the pixel electrode 226 is the anode and the common electrode 234 is the cathode.

The pixel electrode 226 is arranged on the flattening film 222. The pixel electrode 226 is arranged for each pixel 103. The pixel electrode 226 is connected to the source electrode or drain electrode 218_2 of the transistor 210 via a contact hole arranged in the flattening film 222. A highly reflective metal film is used as the pixel electrode 226. Alternatively, a stacked structure of a high-work-function transparent conductive layer such as an indium-oxide-based transparent conductive layer (e.g., ITO) or a zinc-oxide-based transparent conductive layer (e.g., IZO, ZnO) and a metal film can be used as the pixel electrode 226.

An insulating film 228 is arranged to cover an end portion of the pixel electrode 226. The insulating film 228 may also be referred to as a barrier or a bank. Photosensitive acryl is used as the insulating film 228 in the same manner as the flattening film 222. In the insulating film 228, an opening is preferably formed so that the pixel electrode 226 is exposed, and an end portion of the opening is preferably a gently tapered shape. If the end portion of the opening is steep, a coverage defect of the organic layer 232 formed later occurs.

A plurality of organic materials constituting the organic layer 232 is stacked on the pixel electrode 226 and the insulating film 228. The organic layer 232 is arranged by stacking a positive hole transport layer, a light-emitting layer, an electron transport layer, and the like in this order from the pixel electrode 226 side. These layers may be formed by vapor deposition or may be formed by coating after solvent dispersion. In addition, the positive hole transport layer, the electron transport layer, and the like may be selectively formed with respect to each sub-pixel or may be formed on the entire surface of the display region 102.

The common electrode 234 is arranged on the organic layer 232. Since the present embodiment has the top-emission structure, the common electrode 234 needs to have light transmittance. In the case where MgAg is used as the common electrode 234, it is formed in a thin film such that the light emitted from the organic layer 232 is transmitted therethrough. The common electrode 234 is connected to a wiring layer at a cathode contact portion arranged in the peripheral region 109, and is electrically connected to the terminal 107.

A sealing film 240 is arranged on the common electrode 234. The sealing film 240 is arranged to suppress the moisture that has entered from the outside from entering the organic layer 232. The present embodiment shows an example in which the sealing film 240 is formed in a three-layer structure of an inorganic insulating film 236, an organic insulating film 238, and an inorganic insulating film 242. Silicon nitride with high gas barrier properties is preferably used as the inorganic insulating film 236 and 233, and an organic resin material having high flexibility is preferably used as the organic insulating film 238. In addition, a silicon oxide film or an amorphous silicon film may be arranged between the silicon nitride and the organic resin material. As a result, the adhesion between the silicon nitride and the organic resin material can be improved. For example, an overcoat layer may be arranged on the inorganic insulating film 242 for flattening.

A touch sensor 110 is arranged on the sealing film 240. The touch sensor 110 may be formed directly on the sealing film 240. Alternatively, a cover glass on which the touch sensor 110 is formed may be arranged on the sealing film 240.

### <Characteristics of Oxide Semiconductor Layers 208_1 and 208_2>

In an embodiment of the present invention, the oxide semiconductor layers 208_1 and 208_2 have different properties from conventional oxide semiconductors having a polycrystalline structure. Therefore, in order to distinguish the oxide semiconductors included in the oxide semiconductor layers 208_1 and 208_2 from conventional oxide semiconductors having a polycrystalline structure, the oxide semiconductors included in the oxide semiconductor layers 208_1 and 208_2 are hereinafter referred to as Poly-OS (Poly-crystalline oxide semiconductors).

In Poly-OS, a plurality of crystal grains may have one type of crystal structure or a plurality of types of crystal structures, and the like. The crystal structure of Poly-OS can be identified by an electron beam diffraction method or XRD method. In other words, the crystal structure of the oxide semiconductor layers 208_1 and 208_2 can be identified by an electron beam diffraction method or an XRD method.

The oxide semiconductor layers 208_1 and 208_2 containing poly-OS have excellent etching resistance. Specifically, the oxide semiconductor layers 208_1 and 208_2 have a very small etch rate when etched using an etching solution for wet etching. This means that the oxide semiconductor layers 208_1 and 208_2 are hardly etched by the etching solution.

Specifically, the etching rate when the oxide semiconductor layers 208_1 and 208_2 are etched using an etching solution containing phosphoric acid as a main component (for example, mixed acid etching solution) in a temperature range of 35° C. or more and 40° C. (for example, a range including an error of ±5° C. at a set temperature of 40° C.) is less than 3 nm/min, less than 2 nm/min, or less than 1 nm/min. The ratio of phosphoric acid in the mixed acid etching solution is greater than or equal to 50%, greater than or equal to 60%, or greater than or equal to 70%. The mixed acid etching solution may contain acetic acid and nitric acid in addition to phosphoric acid. In contrast, when an oxide semiconductor with an amorphous structure (an oxide semiconductor layer before OS annealing) is etched using the etching solution in a temperature range of 35° C. or more and 40° C. or less, the etching rate of the oxide semiconductor film is greater than or equal to 100 nm/min.

In addition, the etching rate when the oxide semiconductor layers 208_1 and 208_2 of this embodiment are etched using 0.5% of a hydrofluoric acid solution at room temperature (here, refers to 25° C.±5° C.) is less than 5 nm/min, less than 4 nm/min, or less than 3 nm/min. A ratio of hydrogen fluoride in the etching solution is 0.5%. In contrast, when an oxide semiconductor with an amorphous structure is etched using the etching solution, the etching rate is 15 nm/min or higher when etched at room temperature using the etching solution described above.

The etching rates of various oxide semiconductor layers are shown in Table 1. Table 1 shows the etching rates for a mixed acid etching solution and 0.5% of a hydrofluoric acid solution for each prepared sample. The mixed acid etching solution used was “Mixed Acid AT-2F manufactured by Rasa Kogyo Co., Ltd.,” in which the ratio of phosphoric acid in the mixed acid etching solution is 65%. When each sample was etched, the temperature of the mixed acid etching solution was 40° C., and the temperature of 0.5% of the hydrofluoric acid solution was 22° C. In Table 1, Sample 1 is an oxide semiconductor layer with a polycrystalline structure of this embodiment, Sample 2 is an oxide semiconductor layer with an amorphous structure, and Sample 3 is an oxide semiconductor layer containing indium gallium zinc oxide (IGZO) in which the ratio of indium is less than 50%.

TABLE 1

| | | 0.5% of |
|---|---|---|
| | Mixed acid etching | hydrofluoric acid |
| | solution | solution |
| Sample 1 | <0.1 nm/min | <2 nm/min |
| Sample 2 | 111 nm/min | >18 nm/min |
| Sample 3 | 162 nm/min | — |

As shown in Table 1, Sample 1 was hardly etched even with a mixed acid etching solution, and only about 2 nm/min at most with 0.5% of a hydrofluoric acid solution. When etching using the mixed acid etching solution, the etching rate of Sample 1 is less than or equal to 1/100 of the etching rate of Sample 2 (oxide semiconductor film having an amorphous structure before the heat treatment). When etching using 0.5% of the hydrofluoric acid solution, the etching rate of Sample 1 is less than or equal to approximately 1/10 of the etching rate of Sample 2. Further, when etching using the mixed acid etching solution, the etching rate of Sample 1 is less than or equal to 1/100 of the etching rate of Sample 3 (oxide semiconductor film containing IGZO in which the ratio of indium is less than 50%). That is, Sample 1 has significantly better etching resistance than Samples 2 and 3.

Such an excellent etching resistance of the oxide semiconductor layers 208_1 and 208_2 is a characteristic that cannot be obtained with the conventional oxide semiconductor having a polycrystalline structure, which is manufactured by a process lower than or equal to 500° C. Although the detailed mechanism is unknown, the reason for such excellent etching resistance is thought to be that the oxide semiconductor layers 208_1 and 208_2 of this embodiment have a polycrystalline structure different from conventional ones. The same characteristics are also present in the oxide semiconductor layers having a polycrystalline structure described in the Modifications and Embodiments described hereafter.

As described above, the oxide semiconductor layers 208_1 and 208_2 containing the Poly-OS have a very low etching rate with respect to an etching solution. Therefore, it is very difficult to pattern the oxide semiconductor layers 208_1 and 208_2. Thus, when the oxide semiconductor layers 208_1 and 208_2 are formed in an island shape, the oxide semiconductor film having an amorphous structure before the heat treatment is patterned in an island shape, and then the oxide semiconductor film is crystallized by performing the heat treatment. In this way, the island-shaped oxide semiconductor layers 208_1 and 208_2 containing the Poly-OS can be formed.

In the display device 100, the transistor is composed of the oxide semiconductor layers 208_1 and 208_2 having a good polycrystalline structure. As a result, it is possible to obtain electrical characteristics having a mobility of 30 [cm²/Vs] or more, 35 [cm²/Vs] or more, or 40 [cm²/Vs] or more in a range where the channel length L of the channel region CH in the semiconductor device 10 is 2 μm or more and 4 μm or less and the channel width W of the channel region CH is 2 μm or more and 25 μm or less in a transistor including the oxide semiconductor layer 208_1 and 208_2. The mobility in the present embodiment is the field-effect mobility in a saturation region, and the largest value of the field-effect mobility is in a region where a potential difference (Vd) between the source electrode and the drain electrode is greater than a value (Vg−Vth) obtained by subtracting a threshold-voltage (Vth) from a voltage (Vg) supplied to the gate electrode.

### [Manufacturing Method of Display Device]

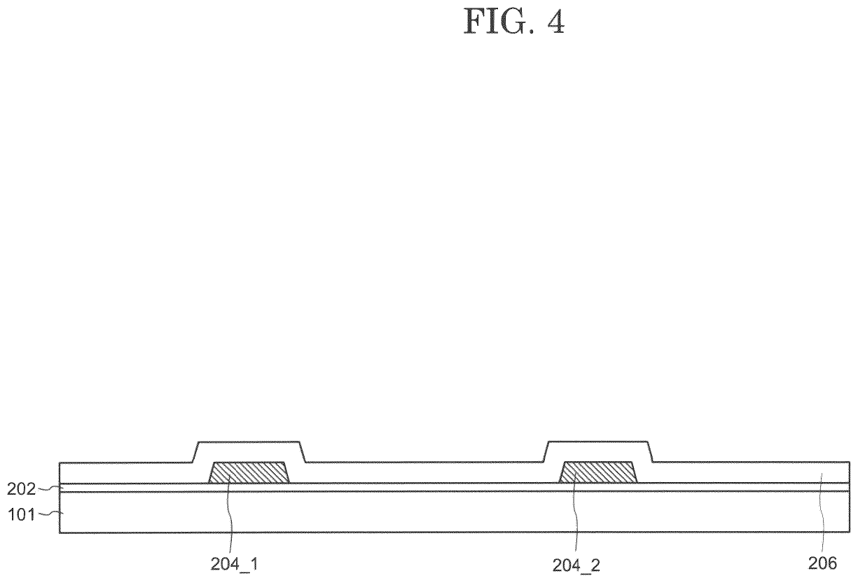

Next, a manufacturing method of the display device 100 according to an embodiment of the present invention will be described with reference to FIG. 4 to FIG. 12.

FIG. 4 is a diagram illustrating a process of forming the base film 202 to the insulating film 206 on the substrate 101. A glass substrate, a quartz substrate, and a flexible substrate (polyimide, polyethylene terephthalate, polyethylene naphthalate, triacetyl cellulose, cyclic olefin copolymer, cycloolefin polymer, and other resin substrates having flexibility) can be used as the substrate 101.

The base film 202 is formed on the substrate 101. Silicon oxide or silicon nitride may be used as the base film 202 in a single layer, or a stacked layer may be used by combining silicon oxide and silicon nitride. The conductive layers 204_1 and 204_2 are formed on the base film 202. The conductive layers 204_1 and 204_2 are formed by forming a conductive film on the base film 202 and processing by a photolithography method. For example, aluminum (Al), titanium (Ti), chromium (Cr), cobalt (Co), nickel (Ni), zinc (Zn), molybdenum (Mo), copper (Cu), indium (In), tin (Sn), hafnium (Hf), tantalum (Ta), tungsten (W), platinum (Pt), bismuth (Bi), and the like can be used as the conductive layers 204_1 and 204_2. In addition, an alloy of these metals may be used.

Next, the insulating film 206 is formed on the conductive layers 204_1 and 204_2. Silicon oxide or silicon nitride may be used as the insulating film 206 in a single layer, or a stacked layer may be used by combining silicon oxide and silicon nitride. In addition, a thickness of the insulating film 206 is preferably larger than a thickness of the insulating film 212 described later. For example, the thickness of the insulating film 206 is 100 nm or more and 500 nm or less, preferably more than 150 nm and 300 nm or less.

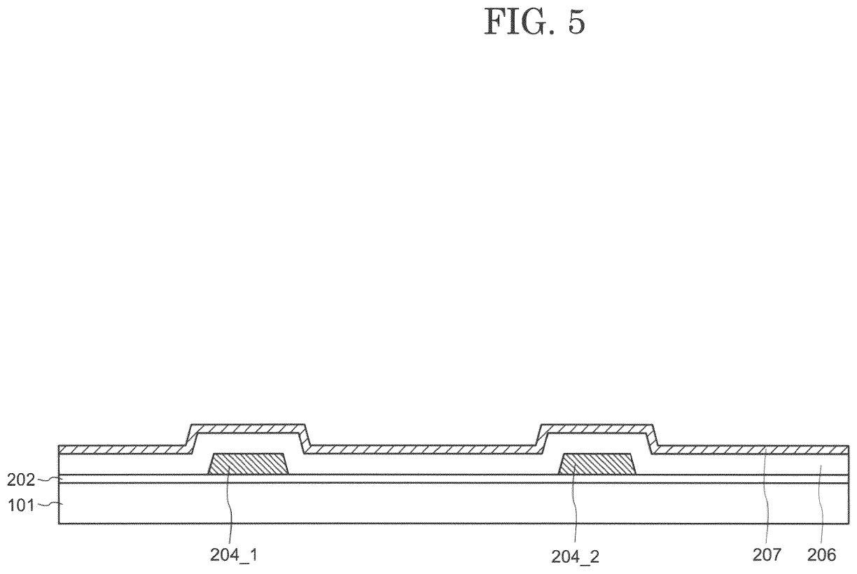

FIG. 5 illustrates the process of depositing an oxide semiconductor film 207 on the insulating film 206.

The oxide semiconductor film 207 is deposited by a sputtering or an atomic layer deposition method (ALD). For example, the thickness of the oxide semiconductor film 207 is 5 nm or more and 50 nm or less, preferably 10 nm or more and 40 nm or less, and more preferably 10 nm or more and 30 nm or less.

A metal oxide having semiconductor properties is used as the oxide semiconductor film 207. For example, an oxide semiconductor containing two or more metals containing indium (In) is used as the oxide semiconductor film 207. The ratio of indium to the entire oxide semiconductor film 207 is 50% or more. Gallium (Ga), zinc (Zn), aluminum (Al), hafnium (Hf), yttrium (Y), zirconia (Zr), and lanthanoids are used as the oxide semiconductor film 207 in addition to indium. Elements other than those described above may be used for the oxide semiconductor film 207.

In the case where the oxide semiconductor film 207 is crystallized by the OS annealing process described below, the oxide semiconductor film 207 after deposition and before the OS annealing process should be amorphous (state with few crystalline components of oxide semiconductors). In other words, the deposition method of the oxide semiconductor film 207 should be under conditions where the oxide semiconductor film 207 immediately after deposition is as non-crystallized as possible. For example, when the oxide semiconductor film 207 is deposited by the sputtering method, the oxide semiconductor film 207 is deposited while controlling the temperature of the object to be deposited (substrate SUB1 and structures formed thereon).

In the case where the deposition is performed on the object to be deposited by the sputtering method, ions generated in the plasma and atoms recoiled by a sputtering target collide with the object to be deposited. Therefore, the temperature of the object to be deposited rises with the deposition process. When the temperature of the object to be deposited rises during the deposition process, the oxide semiconductor film 207 contains microcrystals in the state immediately after deposition, which inhibits crystallization by the subsequent OS annealing process. For example, in order to control the temperature of the object to be deposited as described above, deposition may be performed while cooling the object to be deposited. To control the temperature of the object to be deposited as described above, for example, the deposition may be performed while cooling the object to be deposited. For example, the object to be deposited may be cooled from the opposite side of the surface to be deposited so that the temperature (hereinafter referred to as “deposition temperature”) of the surface to be deposited is 100° C. or less, 70° C. or less, 50° C. or less, or 30° C. or less. By performing the deposition of the oxide semiconductor film 207 while cooling the object to be deposited as described above, the oxide semiconductor film 207 with few crystalline components can be deposited in the state immediately after deposition.

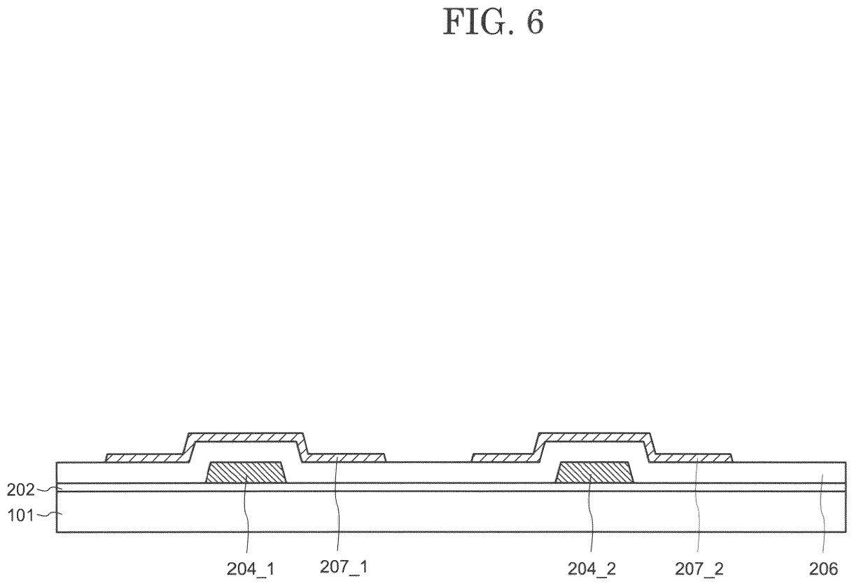

FIG. 6 illustrates the process of forming patterns of the oxide semiconductor layers 207_1 and 207_2 from the oxide semiconductor film 207. A resist mask is formed on the oxide semiconductor film 207, and the oxide semiconductor film 207 is etched using the resist mask. Wet etching may be used, or dry etching may be used as the etching method of the oxide semiconductor film 207. Wet etching may include etching using an acidic etchant. For example, oxalic acid or hydrofluoric acid may be used as the etchant.

The oxide semiconductor film 207 should have a pattern of the oxide semiconductor layers 207_1 and 207_2 formed before the OS annealing process. As mentioned above, when the oxide semiconductor film 207 is crystallized by the OS annealing process, it tends to be difficult to etch because the etching resistance is improved. It is also desirable because even if etching causes damage to the oxide semiconductor film 207, the damage can be repaired by the OS annealing process.

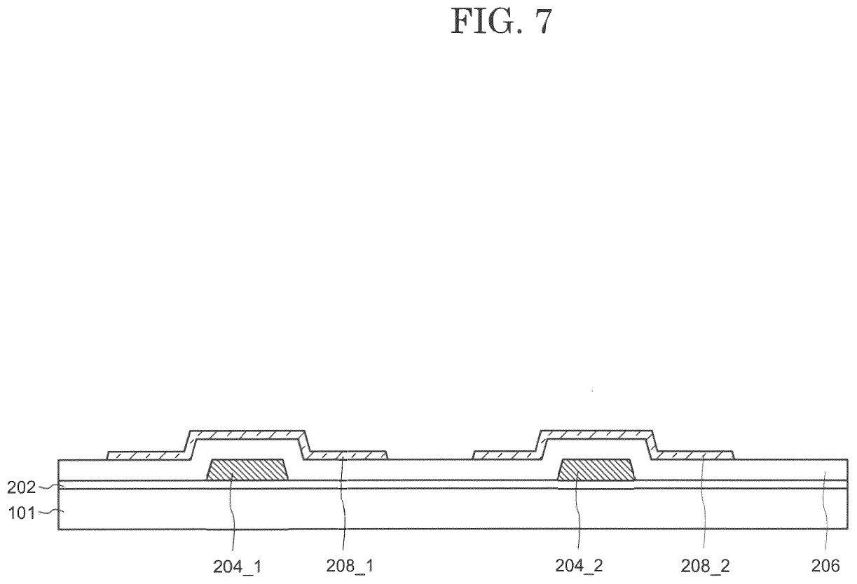

FIG. 7 illustrates the process of a heat treatment (also called OS annealing process) for the oxide semiconductor layers 207_1 and 207_2. In the OS annealing process, the oxide semiconductor layers 207_1 and 207_2 are held at a predetermined attained temperature for a predetermined time. The predetermined attained temperature is 300° C. or more and 500° C. or less, preferably 350° C. or more and 450° C. or less. The holding time at the attained temperature is 15 minutes or more to 120 minutes or less, and preferably 30 minutes or more to 60 minutes or less. By performing the OS annealing process, the oxide semiconductor layers 207_1 and 207_2 are crystallized to form oxide semiconductor layers 208_1 and 208_2 having a polycrystalline structure. This allows the formation of the oxide semiconductor layers 208_1 and 208_2 with high etching resistance.

Next, an insulating film 212 is deposited on the oxide semiconductor layers 208_1 and 208_2.

For the deposition method and the insulating material of the insulating film 212, refer to the description of the insulating film 206. For example, a thickness of the insulating film 212 is 30 nm or more and 150 nm or less.

It is preferable to use an insulating material that contains oxygen for the insulating film 212. It is also preferable to use an insulating film with few defects as the insulating film 212. For example, when the composition ratio of oxygen in insulating film 212 is compared with the composition ratio of oxygen in an insulating film of similar composition to the base film 202 (hereinafter referred to as “other insulating film”), the composition ratio of oxygen in insulating film 212 is closer to the stoichiometric ratio for that insulating film than that of oxygen in the other insulating film. For example, when silicon oxide (SiOx) is used for each of the insulating film 212 and the base film 202, the composition ratio of oxygen in silicon oxide used as the insulating film 212 is closer to the stoichiometric ratio of silicon oxide than the composition ratio of oxygen in silicon oxide used as the base film 202. For example, a layer in which no defects are observed when evaluated by electron spin resonance (ESR) may be used as the insulating film 212.

To form the insulating film 212 with few defects as the insulating film 212, the insulating film 212 may be deposited at a deposition temperature of 350° C. or higher. After depositing the insulating film 212, a process of oxygen implantation to a part of the insulating film 212 may be performed. In this embodiment, silicon oxide is formed as the insulating film 212 at a deposition temperature of 350° C. or higher to form an insulating film with fewer defects.

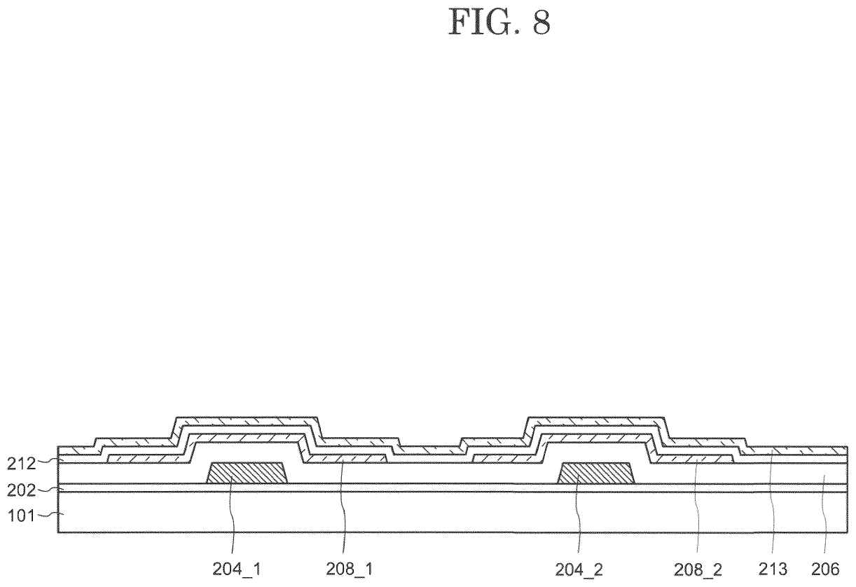

FIG. 8 illustrates the process of depositing an aluminum-based metal oxide film 213 on the insulating film 212.

The metal oxide film 213 is a metal oxide with aluminum as the main component. For example, inorganic insulating materials such as aluminum oxide (AlOₓ), aluminum nitride oxide (AlOₓN_{y}), aluminum nitride (AlNₓO_{y}), and aluminum nitride (AlNₓ) are used as the metal oxide film 213. AlOₓN_{y} described above is a silicon compound and an aluminum compound containing nitrogen (N) in a ratio (x>y) smaller than that of oxygen (O). AlNₓO_{y} is a silicon compound and an aluminum compound containing oxygen in a ratio (x>y) smaller than that of nitrogen.

The “metal oxide film containing aluminum as the main component” means that the ratio of aluminum contained in the metal oxide film 213 is 1% or more of the total amount of the metal oxide film 213. The ratio of aluminum contained in the metal oxide film 213 may be 5% or more and 70% or less, 10% or more and 60% or less, or 30% or more and 50% or less of the total amount of the metal oxide film 213. The above ratio may be a mass ratio or a weight ratio.

For example, the metal oxide film 213 is deposited by sputtering. For example, a thickness of the metal oxide film 213 is 5 nm or more and 100 nm or less, 5 nm or more and 50 nm or less, 5 nm or more and 30 nm or less, or 7 nm or more and 15 nm or less.

For example, when the metal oxide film 213 is formed by sputtering, oxygen is hammered into the insulating film 212 by the deposition of the metal oxide film 213. Therefore, the process gas used in sputtering remains in the insulating film 212. For example, when Ar is used as the process gas for sputtering, Ar may remain in the insulating film 212. The residual Ar can be detected by SIMS (Secondary Ion Mass Spectrometry) analysis of the insulating film 212.

In the present embodiment, aluminum oxide is used as the metal oxide film 207. Aluminum oxide has high barrier properties against gas such as oxygen and hydrogen. In the present embodiment, the aluminum oxide used as the metal oxide film 207 blocks hydrogen and oxygen released from the insulating layer 212, and suppresses the released hydrogen and oxygen.

With the insulating film 212 deposited on the oxide semiconductor layers 208_1 and 208_2 and the metal oxide film 213 deposited on the insulating film 212, a heat treatment (Annealing for Oxidation) is performed to provide oxygen to the oxide semiconductor layers 208_1 and 208_2.

In the process from the deposition of the oxide semiconductor layers 208_1 and 208_2 to the deposition of the insulating film 212 on the oxide semiconductor layers 208_1 and 208_2, a large amount of oxygen deficiencies occur in the upper surface and the side surface of the oxide semiconductor layers 208_1 and 208_2. Therefore, there are more oxygen deficiencies formed near the upper surface of the oxide semiconductor layers 208_1 and 208_2 than the oxygen deficiencies formed near the lower surface of the oxide semiconductor layers 208_1 and 208_2. That is, the oxygen deficiencies in the oxide semiconductor layers 208_1 and 208_2 do not exist uniformly in a thickness direction of the oxide semiconductor layers 208_1 and 208_2, but exist in a non-uniform distribution in the thickness direction of the oxide semiconductor layers 208_1 and 208_2. Specifically, there are fewer oxygen deficiencies in the oxide semiconductor layers 208_1 and 208_2 toward the lower surface side of the oxide semiconductor layers 208_1 and 208_2 and more oxygen deficiencies toward the upper surface side of the oxide semiconductor layers 208_1 and 208_2.

In this embodiment, the oxidation annealing is performed with the metal oxide film 213 on the oxide semiconductor layers 208_1 and 208_2. As a result, the oxygen hammered into the insulating film 212 during the above described oxidation annealing is blocked by the metal oxide film 213, thus preventing the oxygen from being released into the atmosphere. The oxygen released from the insulating film 206 is supplied to the upper surface and the side surface of the oxide semiconductor layers 208_1 and 208_2. As a result, the oxygen is efficiently supplied to the oxide semiconductor layers 208_1 and 208_2, and oxygen deficiencies can be repaired.

Next, the metal oxide film 213 is etched (removed) after the oxidation annealing process. Wet etching or dry etching may be used to etch the metal oxide film 213. For example, dilute hydrofluoric acid (DHF) is used for wet etching. The etching removes the metal oxide film 213 formed on the entire surface. In other words, the metal oxide film 213 is removed without using a mask. In other words, the etching removes all of the metal oxide film 213 in the region overlapping the oxide semiconductor layers 208_1 and 208_2 formed in at least one pattern in a plan view.

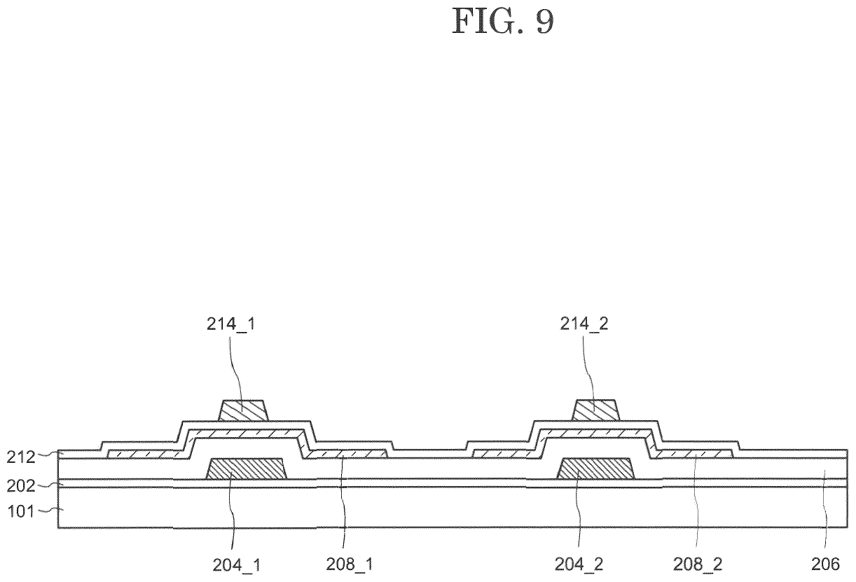

FIG. 9 illustrates the process of forming the conductive layers 214_1 and 214_2 on the insulating film 212. The conductive layers 214_1 and 214_2 are formed by forming a conductive film on the insulating layer 212 and processing it by photolithography. For example, the same materials as the conductive layers 204_1 and 204_2 can be used as the conductive layers 214_1 and 214_2. The conductive layer 214_1 is formed in the region overlapping the conductive layer 204_1 and the oxide semiconductor layer 208_1, and the conductive layer 214_2 is formed in the region over lapping the conductive layer 204_2 and the oxide semiconductor layer 208_2.

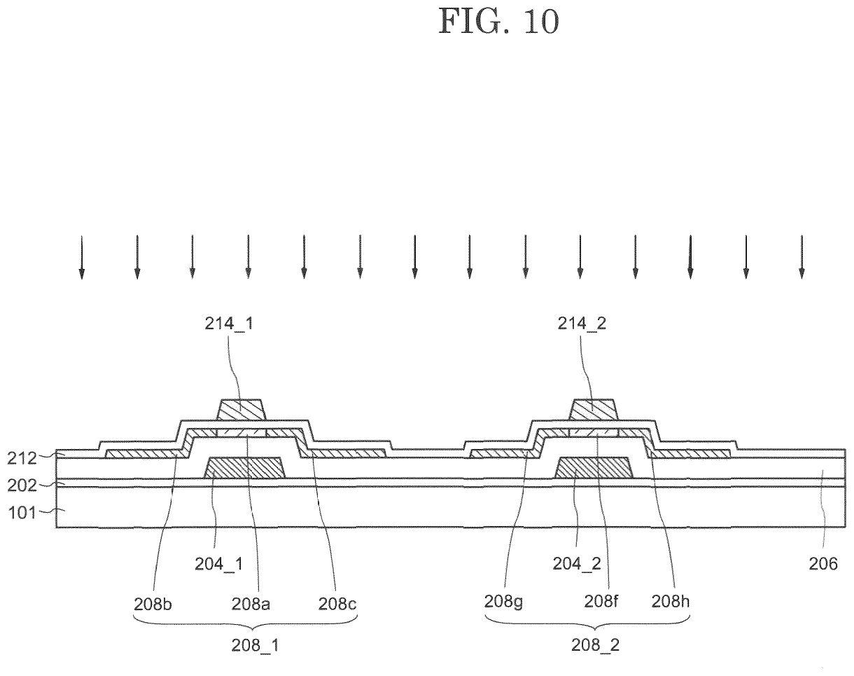

FIG. 10 illustrates the process of adding impurity elements to the oxide semiconductor layers 208_1 and 208_2 by ion implantation. In this embodiment, the case where impurities are added by ion implantation is described, but impurities may also be added by the ion doping method.

Specifically, by the ion implantation, impurity elements are added to the oxide semiconductor layers 208_1 and 208_2 through the insulating layer 212 to form the high concentration impurity regions 208b, 208c, 208g, and 208h. In the oxide semiconductor layers 208_1 and 208_2, the regions overlapping the gate wiring GL1 are the channel regions 208a and 208f. For example, argon (Ar), phosphorus (P), or boron (B) can be used as impurity elements. When boron (B) is added by the ion implantation method, the acceleration energy should be 20 keV or more and 40 keV or less, and the amount of boron (B) implanted should be 1×10¹⁴ cm⁻² or more and 1×10¹⁶ cm⁻² or less.

The concentration of impurity elements contained in the high concentration impurity regions 208b, 208c, 208g, and 208h should be 1×10¹⁸ cm⁻³ or more and 1×10²¹ cm⁻³ or less as measured by SIMS analysis (secondary ion mass spectrometry). When the high concentration impurity regions 208b, 208c, 208g, and 208h contain impurities of 1×10¹⁸ cm⁻³ or more and 1×10²¹ cm⁻³ or less, it is presumed that impurity elements were intentionally added by ion implantation or doping methods.

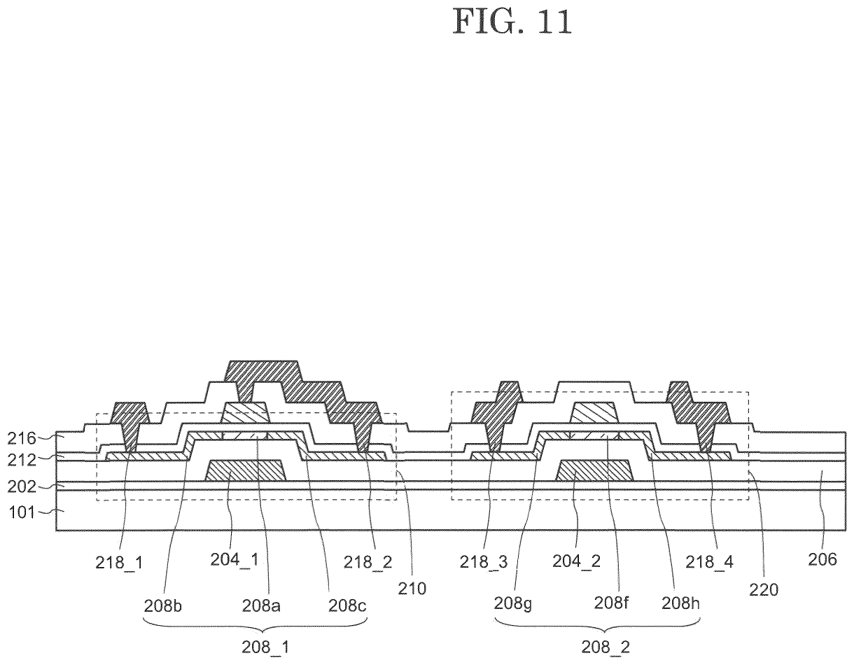

FIG. 11 is a diagram illustrating a process of forming the source electrodes and the drain electrodes 218_1 to 218_4 from the insulating film 216 on the oxide semiconductor layers 208_1 and 208_2. First, the insulating film 216 is formed on the oxide semiconductor layers 208_1 and 208_2. Silicon oxide or silicon nitride may be used as the insulating film 216 in a single layer, or a stacked layer may be used by combining silicon oxide and silicon nitride. In addition, a thickness of the insulating film 216 is preferably larger than the thickness of the insulating film 212. For example, the thickness of the insulating film 216 is preferably 250 nm or more and 600 nm or less. By using silicon nitride as the insulating film 216, hydrogen contained in silicon nitride is introduced into oxygen deficiencies formed by ion implantation in the oxide semiconductor layers 208_1 and 208_2. This makes the high concentration impurity regions 208b, 208c, 208g, and 208h more low-resistance.

Next, a contact hole reaching the oxide semiconductor layers 208_1 and 208_2 and the conductive layer 214_1 is formed in the insulating film 212 and the insulating film 216. Next, the source electrodes or drain electrodes 218_1 to 218_4 are formed on the insulating film 216. The source electrodes or drain electrodes 218_1 to 218_4 are formed by forming a conductive film on the insulating film 216 and processing the conductive film by a photolithography method. Therefore, the source electrode or drain electrode 218_1 is connected to the high concentration impurity region 208b, and the source electrode or drain electrode 218_2 is connected to the high concentration impurity region 208c and the conductive layer 214_1. The source electrode or drain electrode 218_3 is connected to the high concentration impurity region 208g, and the source electrode or drain electrode 218_4 is connected to the high concentration impurity region 208h. The same materials as those of the conductive layers 204_1 and 204_2 can be used as the source electrodes and the drain electrodes 218_1 to 218_4. Although not shown, a contact hole reaching the conductive layer 204_1 may be formed in the insulating films 206, 212, and 216 during this process. Therefore, the conductive layer 204_1 and the source electrode or drain electrode 218_3 can be connected to each other. Through the steps so far, the transistors 210 and 220 can be formed.

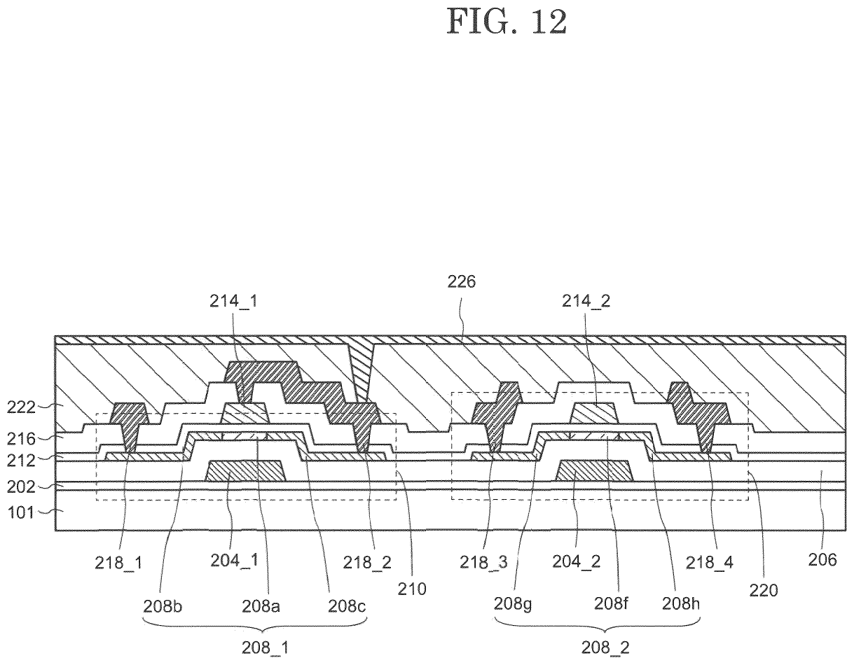

FIG. 12 is a diagram illustrating a process of forming the flattening film 222 and the pixel electrode 226. The flattening film 222 is formed on the source or drain electrodes 218_1 to 218_4. An organic resin material such as polyimide, acryl, or epoxy can be used as the flattening film 222. These materials can be formed into films by a solution coating method and have a high flattening effect.

The light-emitting element 230 is formed by forming the pixel electrode 226, the organic layer 232, and the common electrode 234. First, a contact hole reaching the source electrode or drain electrode 218_2 is formed in the flattening film 222. Next, the pixel electrode 226 is formed on the flattening film 222. The pixel electrode 226 is formed by forming a conductive film on the flattening film 222 and processing the conductive film by a photolithography method. The insulating film 228 is formed such that the pixel electrode 226 is exposed. Next, a plurality of organic materials constituting the organic layer 232 is formed on the pixel electrode 226 and the insulating film 228. Next, the common electrode 234 is formed on the organic layer 232.

After that, the inorganic insulating film 236, the organic insulating film 238, and the inorganic insulating film 242 are formed on the common electrode 234 to form the sealing film 240. First, the inorganic insulating film 236 is formed on the common electrode 234. Next, the organic insulating film 238 is formed on the inorganic insulating film 236. Next, the inorganic insulating film 242 is formed on the organic insulating film 238. In this case, an end portion of the inorganic insulating film 236 is preferably in contact with an end portion of the inorganic insulating film 242 to seal the organic insulating film 238. As a result, it is possible to suppress the light-emitting element 230 from deteriorating due to the entry of moisture from the outside of the sealing film 240.

Through the above steps, the display device 100 having the structure of the pixel 103 shown in FIG. 3 can be manufactured.

According to a manufacturing method of the display device 100 according to an embodiment of the present invention, it is possible to more easily form two types of transistors that have different properties and structures without increasing the number of processes even in a small region within one pixel.

### First Modification

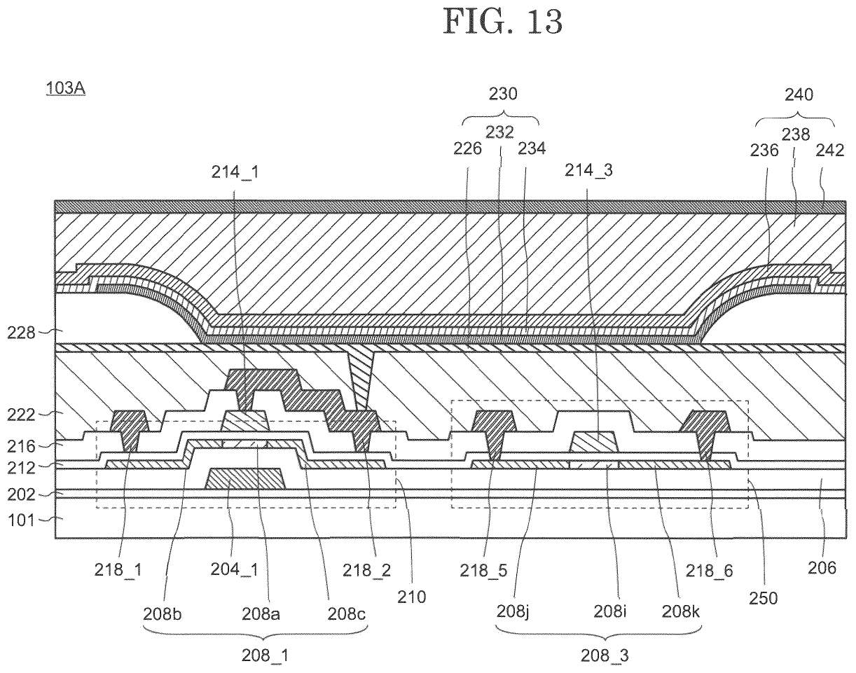

Next, a pixel 103A having a structure partially different from the structure of the pixel 103 shown in FIG. 3 will be described with reference to FIG. 13.

FIG. 13 is a diagram illustrating a cross-sectional structure of the pixel 103A of the display device 100 according to an embodiment of the present invention. As shown in FIG. 13, the transistor 210 and a transistor 250 are arranged on the substrate 101 via the base film 202. In this case, the transistor 210 corresponds to the driving transistor DRT shown in FIG. 3, and the transistor 250 corresponds to the writing transistor SST shown in FIG. 3. In addition, since the structure of the transistor 210 is the same as that of the transistor 210 shown in FIG. 3, the description thereof is omitted.

The transistor 250 functioning as the writing transistor SST has a top gate structure. The transistor 250 has at least an oxide semiconductor layer 208_3 arranged on the insulating film 206, the insulating film 212 arranged on the oxide semiconductor layer 208_3, and a conductive layer 214_3 arranged on the insulating film 212. In this case, the control terminal for controlling switching of the transistor 250 is the conductive layer 214_3. The insulating film 212 functions as a gate insulating film. The oxide semiconductor layer 208 includes a channel region 208i and high concentration impurity regions 208j and 208k. The insulating film 212 is arranged on the conductive layer 214_3. Source electrode and drain electrodes 218_5 and 218_6 are arranged on the insulating film 212. The source electrode or drain electrodes 218_5 and 218_6 are connected to the high concentration impurity regions 208j and 208k via the contact holes arranged in the insulating films 212 and 216.

Since the gate insulating film of the writing transistor SST can be made thinner than the gate insulating film of the driving transistor DRT, an electric field is easily applied to the oxide semiconductor layer 208_3, and the ON current can be increased. In addition, since the channel length L can be shortened, the switching characteristic is improved. On the other hand, since the gate insulating film of the driving transistor DRT can be made thicker than the gate insulating film of the writing transistor SST, the electric field is less likely to be applied to the oxide semiconductor layer 208_1, and the ON current can be made smaller. In particular, since the change in the current of the driving transistor DRT can be reduced in the low gradation region controlled by the small current, it is possible to finely control the gradation. As a result, it is possible to suppress the occurrence of display unevenness in the display region 102. Further, since a large amount of current can be suppressed from flowing through the driving transistor DRT, it is possible to suppress a decrease in reliability due to thermal degradation.

Furthermore, since the crystallized oxide semiconductor layers 208_1 and 208_2 have high etching resistance, the decrease in film thickness from the oxide semiconductor layer 207 deposited to the crystallized oxide semiconductor layers 208_1 and 208_2 can be suppressed. Therefore, the thickness of the oxide semiconductor film 207 to be deposited can be reduced, and the thickness of the crystallized oxide semiconductor layers 208_1 and 208_2 can be reduced. This allows the field-effect mobility to be improved by increasing the current density in the strong electric field range when the gate voltage is applied. In addition, the etching can suppress the phenomenon of the thickness of the crystallized oxide semiconductor layers 208_1 and 208_2, thereby suppressing the variation of the film thickness within the substrate plane. As a result, the characteristic variation of the transistor within the substrate plane can also be suppressed, and thus the display irregularities in the display region 102 can be suppressed.

### Second Embodiment

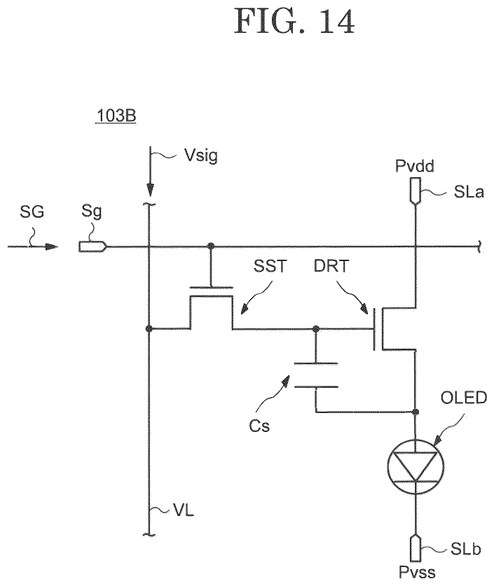

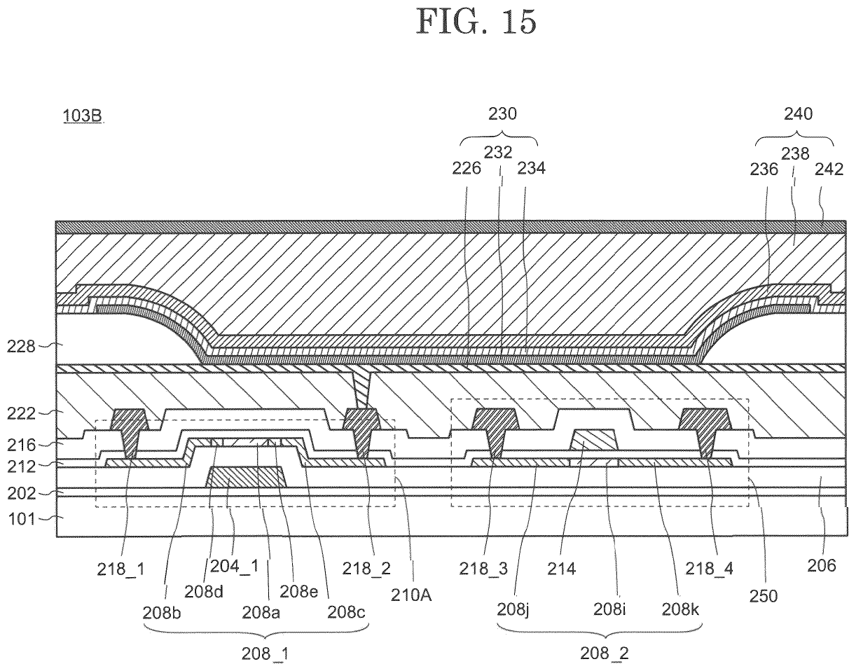

In the present embodiment, a structure of a pixel 103B having a structure partially different from the structure of the pixel 103 described in the first embodiment will be described with reference to FIG. 14 and FIG. 15. In addition, in the structure of the pixel 103B, parts having the same or similar functions as those of the pixel 103 are denoted by the same reference signs, and a repeated explanation thereof is omitted.

### [Equivalent Circuit Diagram]

FIG. 14 is an equivalent circuit diagram of the pixel 103B included in the display device 100 according to an embodiment of the present invention. The equivalent circuit diagram shown in FIG. 14 is different from the equivalent circuit diagram shown in FIG. 2 in the structure of the driving transistor DRT. In FIG. 14, the driving transistor DRT is the bottom gate drive, and the writing transistor SST is the top gate drive.

### [Cross-Sectional Structure of Pixel]

FIG. 15 is a diagram illustrating a cross-sectional structure of the pixel 103B of the display device 100 according to an embodiment of the present invention. As shown in FIG. 15, a transistor 210A and the transistor 250 are arranged on the substrate 101 via the base film 202. In this case, the transistor 250 corresponds to the writing transistor SST shown in FIG. 14, and the transistor 210A corresponds to the driving transistor DRT shown in FIG. 14. In addition, since the structure of the transistor 250 is the same as the structure of the transistor 250 shown in FIG. 13, detailed descriptions thereof will be omitted.

The transistor 210A functioning as the driving transistor DRT has a bottom gate structure. The transistor 210A includes at least the conductive layer 204_1, the insulating film 206 arranged on the conductive layer 204_1, and the oxide semiconductor layer 208_1 arranged on the insulating film 206. In this case, the oxide semiconductor layer 208_1 includes the channel region 208a, the high concentration impurity regions 208b and 208c, and low concentration impurity regions 208d and 208e. The low concentration impurity regions 208d and 208e are arranged with the channel region 208a interposed therebetween. The high concentration impurity regions 208b and 208c are arranged adjacent to the low concentration impurity regions 208d and 208e. In this case, the channel region 208a and the low concentration impurity regions 208d and 208e overlap the conductive layer 204_1. The insulating film 206 functions as the gate insulating film of the transistor 210. The insulating film 212 is arranged on the oxide semiconductor layer 208_1 and the insulating film 216 is further arranged on the insulating film 212. The thickness of the insulating film 206 is preferably larger than the thickness of the insulating film 212. The thickness of the insulating film 206 is 100 nm or more and 400 nm or less, more preferably more than 150 nm and 300 nm or less. The thickness of the insulating film 212 is 30 nm or more and 150 nm or less. The source electrode and the drain electrode 218_1 and 218_2 are arranged on the insulating film 216. The source electrode and the drain electrode 218_1 and 218_2 are connected to the high concentration impurity regions 208b and 208c via the contact holes arranged in the insulating films 212 and 216. Although not shown, the conductive layer 204_1 is electrically connected to one of the source electrode and the drain electrode 218_3 and 218_4.

In the transistor 210A shown in FIG. 15, the low concentration impurity regions 208d and 208e are arranged between the channel region 208a and the high concentration impurity regions 208b and 208c in the oxide semiconductor layer 208_1. As a result, the electric field applied in the vicinity of the end portion of the channel region 208a is reduced, so that the source/drain resistance can be improved. Since the low concentration impurity regions 208d and 208e overlap the conductive layer 204_1, the source/drain resistance can be further improved.

As shown in FIG. 15, in the display device 100, a transistor with a top gate structure is arranged as the writing transistor SST and a transistor with a bottom gate structure is arranged as the driving transistor DRT on the same substrate. In this case, among the insulating films 206 and 212 vertically sandwiching the oxide semiconductor layers 208_1 and 208_2, the insulating film 212 functions as a gate insulating film in the writing transistor SST, and the insulating film 206 functions as a gate insulating film in the driving transistor DRT. In this case, the thickness of the insulating film 212 is smaller than the thickness of the insulating film 206. Therefore, the thicknesses of gate insulating films can be made different between the writing transistor SST and the driving transistor DRT. That is, a thin gate insulating film can be applied to the SST in the top gate drive, and a thick gate insulating film can be applied to the driving transistor DRT in the bottom gate drive.

Since the gate insulating film of the writing transistor SST can be made thinner than the gate insulating film of the driving transistor DRT, an electric field is easily applied to the oxide semiconductor layer 208_2, and the ON current can be increased. In addition, in the writing transistor SST, since the impurity element is added to the oxide semiconductor layer 208_2 via the conductive layer 214_2, the channel length L can be shortened. This makes it possible to reduce the S value of the writing transistor SST. On the other hand, since the gate insulating film of the driving transistor DRT can be made thicker than the gate insulating film of the writing transistor SST, the electric field is less likely to be applied to the oxide semiconductor layer 208_1, and the ON current can be made smaller. In particular, since the change in the current of the driving transistor DRT can be reduced in the low gradation region controlled by the small current, it is possible to finely control the gradation. As a result, it is possible to suppress the occurrence of display unevenness in the display region 102. Further, since a large amount of current can be suppressed from flowing through the driving transistor DRT, it is possible to suppress a decrease in reliability due to thermal degradation. In addition, as described in the first embodiment, in the case of performing the dual gate drive in the writing transistor SST, the BT stress of the gate is more significant than in the case of performing the one-side gate drive. Therefore, although there is an advantage that the on-off characteristics of the transistor become sharp, the reliability may be slightly sacrificed. Therefore, in the case where the driving capability is sufficiently high in the top gate driving and a back surface does not need to be shielded from light, the reliability can be improved by omitting the gate electrode on the bottom side.

### [Manufacturing Method for Display Device]

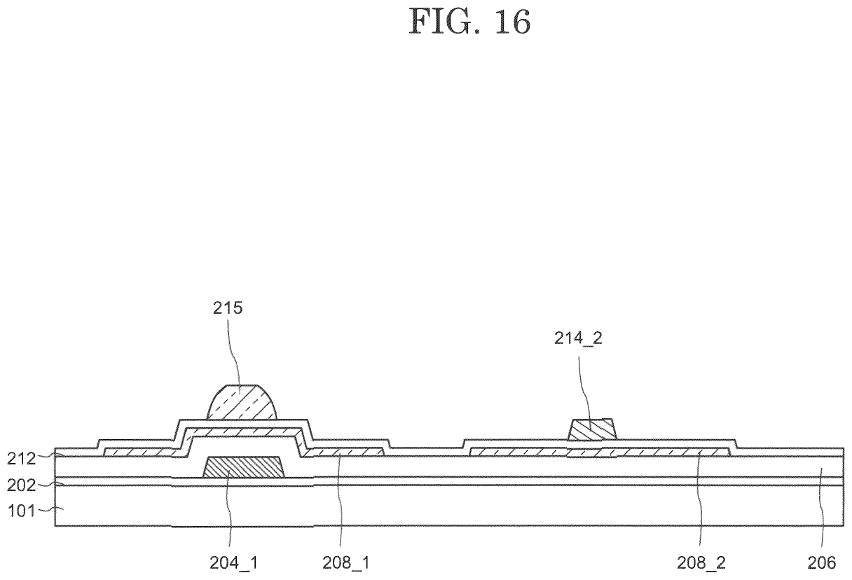

Next, the method for manufacturing the display device 100 according to an embodiment of the invention will be described with reference to FIG. 16 to FIG. 18. The process from the formation of the base film 202 on the substrate 101 to the oxidation annealing process can be referred to in the explanation in FIG. 4 to FIG. 8.

FIG. 16 is a diagram illustrating a process of forming the conductive layer 214_2 and a resist mask 215 on the insulating film 212. First, the conductive layer 214_2 is formed on the insulating film 212. A conductive layer 214_4 is formed by forming a conductive film on the insulating film 212 and processing by a photolithography method. The conductive layer 214_2 is formed in a region overlapping the oxide semiconductor layer 208_2. Next, the resist mask 215 is formed on a part of the region overlapping the oxide semiconductor layer 208_1 arranged on the insulating film 212. In this case, the resist mask 215 is formed so that an end portion has a tapered shape. The resist mask 215 is not limited to a tapered shape as long as the thickness of the resist mask is reduced as it approaches the end portion.

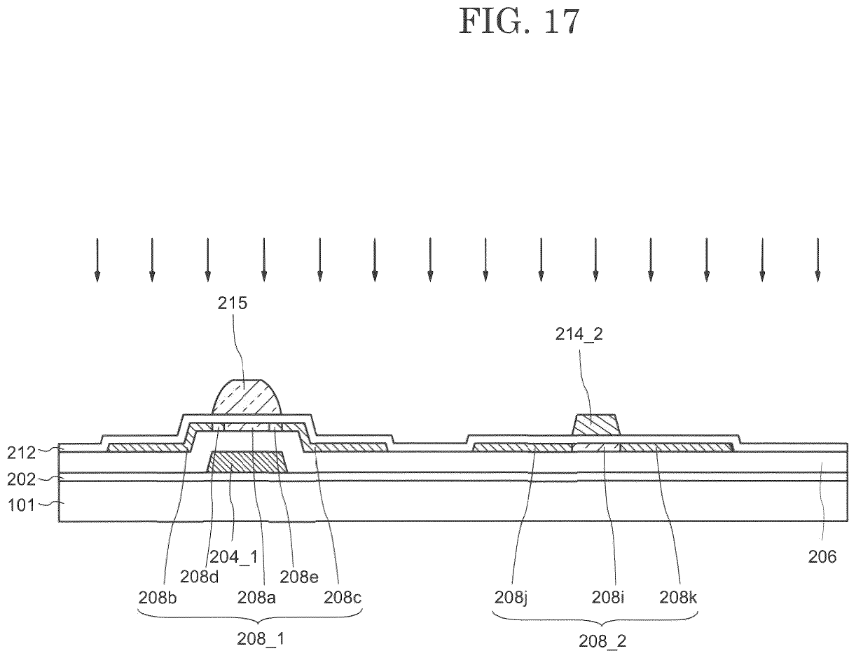

FIG. 17 is a diagram illustrating a step of adding an impurity element to the oxide semiconductor layers 208_1 and 208_2 by ion-implantation. Impurity elements are added to the oxide semiconductor layers 208_1 and 208_2 by ion-implantation using the conductive layer 214_2 and the resist mask 215 as masks. As a result, in the oxide semiconductor layer 208_2, the high concentration impurity regions 208g and 208h are formed in the region not overlapping the conductive layer 214_2, and the channel region 208f is formed in the region overlapping the conductive layer 214_2. The concentration of impurity elements in the high concentration impurity regions 208g and 208h should be 1×10¹⁸ cm⁻³ or more and 1×10²¹ cm⁻³ or less as measured by SIMS analysis (secondary ion mass spectrometry). At the same time, in the oxide semiconductor layer 208_1, the high concentration impurity regions 208b and 208c are formed in a region where the resist mask 215 does not overlap. In addition, in a region where the resist mask 215 overlaps the tapered shape, the impurity element is added via the resist mask 215, so that the low concentration impurity regions 208d and 208e are formed. In addition, within the resist mask 215, the channel region 208a is formed in a region overlapping a part other than the tapered shape. The concentration of impurity elements in the high concentration impurity regions 208b and 208c should be 1×10¹⁸ cm⁻³ or more and 1×10²¹ cm⁻³ or less as measured by SIMS analysis. In addition, impurity elements are added to the low concentration impurity regions 208d and 208e through the resist mask 215. Therefore, the concentration of impurities added to the low concentration impurity regions 208d and 208e is relatively lower than the concentration of impurities added to the high concentration impurity regions 208b and 208c. For example, when the slope of the side surface of resist mask 215 is properly controlled, the concentration of impurities added to low concentration impurity regions 208d and 208e can be one order of magnitude lower than the concentration of impurities added to high concentration impurity regions 208B and 208C. Therefore, the concentration of impurity elements in the low concentration impurity regions 208d and 208e is less than 1×10¹⁸ cm⁻³ as measured by SIMS analysis. As a result, the conductivities of the low concentration impurity regions 208d and 208e are smaller than the conductivities of the high concentration impurity regions 208b and 208c. In other words, the electrical resistivity of the low concentration impurity regions 208d and 208e is higher than that of the high concentration impurity regions 208b and 208c. In other words, the sheet resistivity of the low concentration impurity regions 208d and 208e is greater than that of the high concentration impurity regions 208b and 208c. The region where the thickest region of the resist mask 215 overlaps the oxide semiconductor layer 208_1 determines the channel region of the transistor 210A. When the thickest region of the resist mask 215 is 2 μm or more and 4 μm or less, the channel length L can also be 2 μm or more and 4 μm or less. However, the channel length L of the transistor 210A and the channel length L of the transistor 250 may be the same or different as long as they are 2 μm or more and 4 μm or less.

Adding the impurity element to the oxide semiconductor layers 208_1 and 208_2 causes crystal defects in the oxide semiconductor layers 208_1 and 208_2, which reduces the resistance of the region. The resistance of the oxide semiconductor layers 208_1 and 208_2 can be reduced depending on the concentration of the added impurity element. Therefore, the resistance of the high concentration impurity regions 208b, 208c, 208g, and 208h can be made lower than the resistance of the low concentration impurity regions 208d and 208e. In addition, using the resist mask 215 and the conductive layer 214_2 having a tapered shape as masks makes it possible to form a structure having the low concentration impurity regions 208d and 208e in the oxide semiconductor layer 208_1 in one addition process of impurity elements, so that it is possible to form a structure having no low concentration impurity regions in the oxide semiconductor layer 208_2. On the other hand, the resistance remains high because the channel regions 208a and 208f have less crystalline defects and less hydrogen concentration. In this way, different oxide semiconductor layers 208_1 and 208_2 may be formed in the same process. In addition, the resist mask 215 is removed after the impurity element is added.

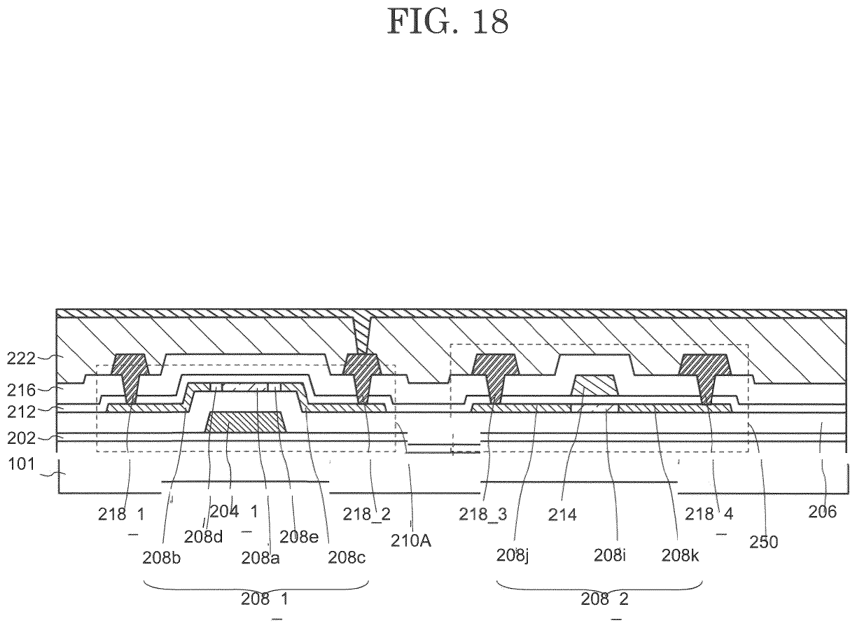

FIG. 18 is a diagram illustrating a process of forming the insulating film 116 to the process of forming the pixel electrode 226. The process of forming the pixel electrode 226 from the process of forming the insulating film 216 may be described with reference to FIG. 12. In addition, the manufacturing methods described in the first embodiment may be applied from the step of forming the insulating film 228 to the step of forming the inorganic insulating film 242.

Through the above steps, the display device 100 having the structure of the pixel 103B shown in FIG. 15 can be manufactured.

According to the manufacturing method of the display device 100 according to an embodiment of the present invention, it is possible to easily form two types of transistors that have different properties and structures without increasing the number of processes even in a small region within one pixel. In particular, the oxide semiconductor layer 208_1 including the high concentration impurity regions 208b and 208c and the low concentration impurity regions 208d and 208e and the oxide semiconductor layer 208_2 including the high concentration impurity regions 208g and 208h can be simultaneously formed.

### Second Modification

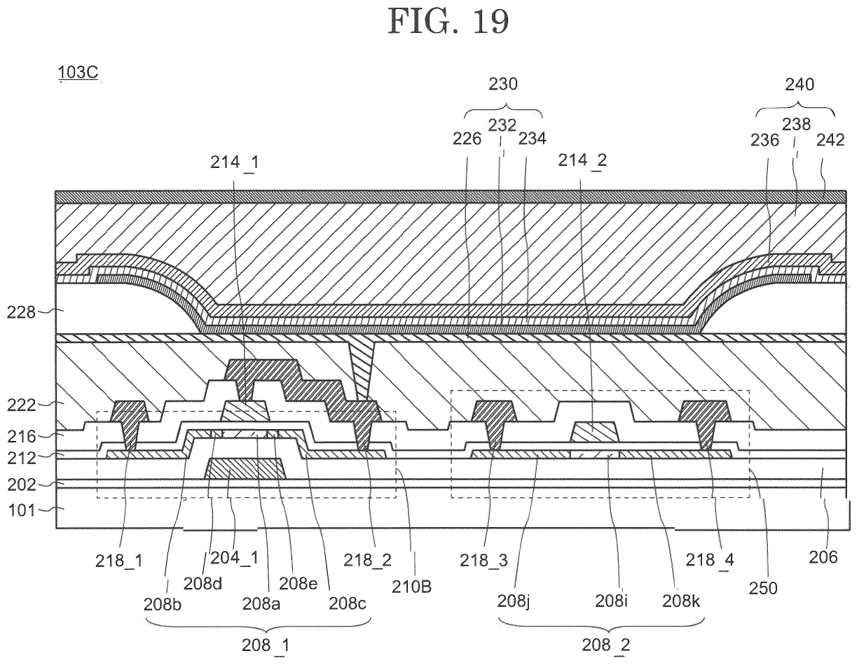

FIG. 19 is a diagram illustrating a cross-sectional structure of a pixel 103C of the display device 100 according to an embodiment of the present invention. As shown in FIG. 19, a transistor 210B and the transistor 250 are arranged on the substrate 101 via the base film 202. In this case, the transistor 250 corresponds to the writing transistor SST shown in FIG. 13, and the transistor 210B corresponds to the driving transistor DRT shown in FIG. 13.

In the transistor 210B, in the structure of the transistor 210A, the conductive layer 214_1 and the high concentration impurity region 208b are connected to each other via the source electrode or drain electrode 218_2. In the case where the transistor 210B is formed, after the conductive layers 214_1 and 214_2 are formed, impurity elements are added at a concentration of about 5×10¹² atoms/cm² to 1×10¹⁴ atoms/cm² using the conductive layers 214_1 and 214_2 as masks. After that, a resist mask is formed so as to cover the conductive layer 214_1 and the low concentration impurity regions 208d and 208e, and then the impurity element is added at a concentration of about 1×10¹⁴ atoms/cm² to 5×10¹³ atoms/cm². Therefore, the channel region 208a, the high concentration impurity regions 208b and 208c, and the low concentration impurity regions 208d and 208e may be formed in the oxide semiconductor layer 208_1 included in the driving transistor DRT.

### Third Embodiment

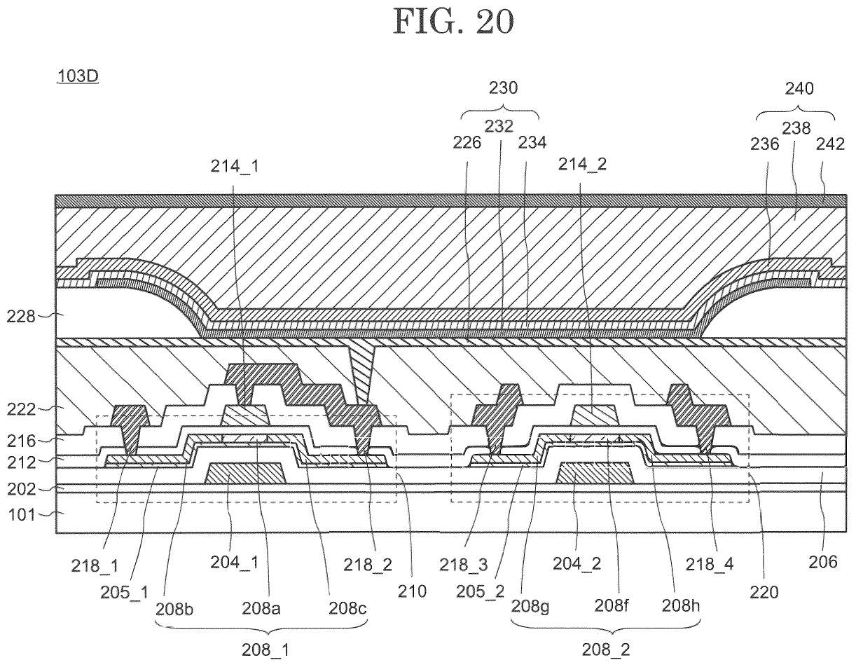

In this embodiment, the configuration of a pixel 103D, which has a partially different configuration from the pixel 103 described in the first and second embodiments, is described with reference to FIG. 20 to FIG. 22. In the pixel 103D, the same part or the part having the same function as the pixel 103 is marked with the same symbol, and repeated explanations are omitted.

FIG. 20 illustrates a cross-sectional configuration of the pixel 103D of the display device according to an embodiment of the invention. As shown in FIG. 20, the case in which the metal oxide layers 205_1 and 205_2 are provided between the insulating film 206 and the oxide semiconductor layers 208_1 and 208_2 is described.

The metal oxide layers 205_1 and 205_2 are aluminum-based metal oxides. For example, inorganic insulating materials such as aluminum oxide (AlOₓ), aluminum nitride oxide (AlOₓN_{y}), aluminum nitride (AlNₓO_{y}), and aluminum nitride (AlNₓ) are used as the metal oxide layers 205_1 and 205_2. A ratio of aluminum in the metal oxide layers 205_1 and 205_2 may be 5% or more and 70% or less, 10% or more and 60% or less, or 30% or more and 50% or less of the total metal oxide layers 205_1 and 205_2. The above ratios may be by mass or by weight.

For example, the thickness of the metal oxide layers 205_1 and 205_2 is 1 nm or more and 10 nm or less, 1 nm or more and 4 nm or less, or 1 nm or more and 3 nm or less. In this embodiment, aluminum oxide is used as the metal oxide layers 205_1 and 205_2. Aluminum oxide has high barrier properties against gases.

### <Manufacturing Method for Display Devices>

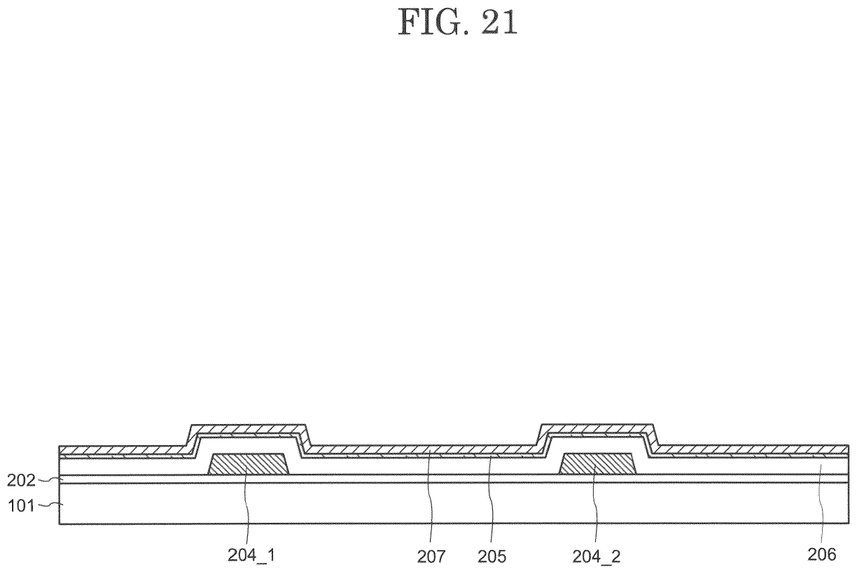

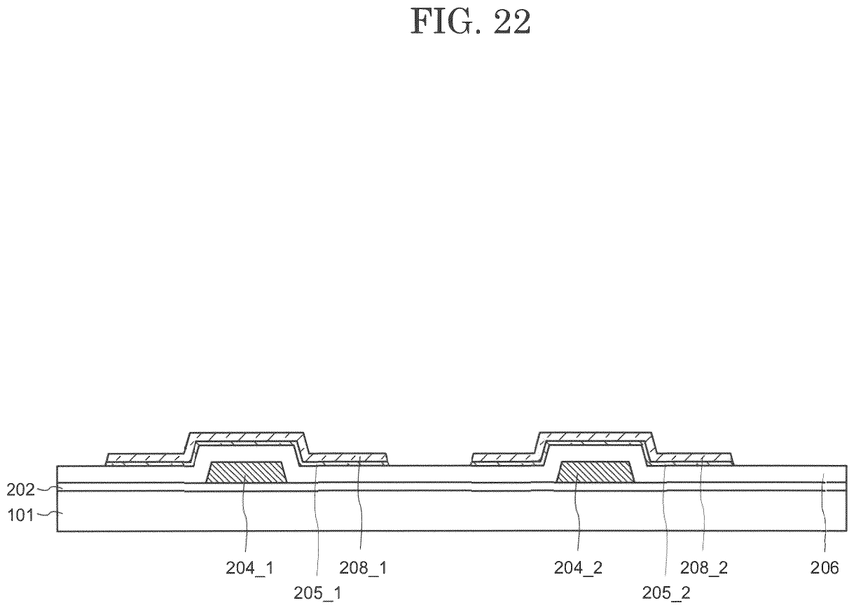

Next, the method for manufacturing the display device 100 according to an embodiment of the invention will be described with reference to FIG. 21 and FIG. 22. The explanation in FIG. 4 can be referred to regarding the process from the formation of the base film 202 to the deposition of the insulating film 206 on the substrate 101.

FIG. 21 illustrates the process of depositing the aluminum-based metal oxide film 205 and the oxide semiconductor film 207 on the insulating film 206. For example, the metal oxide film 205 is deposited by the sputtering method. The thickness of the metal oxide film 205 is 1 nm or more and 10 nm or less, 1 nm or more and 4 nm or less, or 1 nm or more and 3 nm or less.

Next, the oxide semiconductor film 207 is deposited on the metal oxide film 205. For the deposition method of the oxide semiconductor film 207, refer to the description of the deposition of the oxide semiconductor film 207 in FIG. 5.

Next, patterns of the oxide semiconductor layers 207_1 and 207_2 are formed from the oxide semiconductor film 207. For the formation of the pattern of the oxide semiconductor film 207, refer to the description of the pattern formation of the oxide semiconductor film 207 in FIG. 6.

Next, the OS annealing process is performed on the oxide semiconductor layers. For the OS annealing process, refer to the description of the OS annealing process in FIG. 7. The OS annealing process crystallizes the oxide semiconductor layers 207_1 and 207_2 to form the oxide semiconductor layers 208_1 and 208_2 with a polycrystalline structure.

When an oxygen supply process is uniformly applied to the oxide semiconductor layers 208_1 and 208_2 having the above oxygen deficiency distribution, when the amount of oxygen necessary to repair the oxygen deficiencies formed on the top side of the oxide semiconductor layers 208_1 and 208_2 is supplied, the bottom side of the oxide semiconductor layers 208_1 and 208_2 is supplied with an excess amount of oxygen. As a result, defect levels different from oxygen deficiencies are formed on the bottom side of the oxide semiconductors 208_1 and 208_2 due to the excess oxygen. As a result, the phenomena such as characteristic fluctuations in reliability tests or a decrease in field effect mobility occur. Therefore, to suppress such phenomena, it is necessary to supply oxygen to the upper surface of the oxide semiconductor layers 208_1 and 208_2 while suppressing an oxygen supply to the lower surface of the oxide semiconductor layers 208_1 and 208_2.

Oxidation annealing is performed with the metal oxide layers 205_1 and 205_2 under the oxide semiconductor layers 208_1 and 208_2 and the metal oxide film 213 on the oxide semiconductor layers 208_1 and 208_2. As a result, the oxygen hammered into the insulating film 212 during the above oxidation annealing process is blocked by the metal oxide film 213, thus inhibiting its release into the atmosphere. The oxygen released from the insulating film 206 is supplied to the upper and side surfaces of the oxide semiconductor layers 208_1 and 208_2. The metal oxide layers 205_1 and 205_2 can suppress the excessive supply of oxygen to the lower portions of the oxide semiconductor layers 208_1 and 208_2. As a result, the oxygen can be efficiently supplied to the oxide semiconductor layers 208_1 and 208_2 to repair oxygen deficiencies.

FIG. 22 illustrates the process of forming patterns of the metal oxide layers 205_1 and 205_2 from the metal oxide film 205 using oxide semiconductor layers 208_1 and 208_2 having polycrystalline structures. The metal oxide layers 205_1 and 205_2 are etched using the oxide semiconductor layers 208_1 and 208_2 having polycrystalline structures as masks. Wet etching or dry etching may be used to etch the metal oxide layers 205_1 and 205_2. For example, for wet etching, a mixed acid etching solution or 0.5% of a hydrofluoric acid solution is used. As described in the first embodiment, the oxide semiconductor layers 208_1 and 208_2 having a polycrystalline structure have etching resistance to a mixed acid etching solution or 0.5% of a hydrofluoric acid solution compared to the amorphous oxide semiconductor layers 207_1 and 207_2. The oxide semiconductor layers 208_1 and 208_2 having a polycrystalline structure have excellent etching resistance with almost no film thinning due to etching. Therefore, the oxide semiconductor layers 208_1 and 208_2 can be used as masks to etch the metal oxide layers 205_1 and 205_2. This allows the photolithography process to be omitted.

Next, the insulating film 212 is deposited over the oxide semiconductor layers 208_1 and 208_2, and the metal oxide film 213 is deposited over the insulating film 212. For the materials and deposition methods of each of the insulating film 212 and the metal oxide film 213, refer to the description of the insulating film 121 in FIG. 8.

In the process from the deposition of the oxide semiconductor layers 208_1 and 208_2 to the deposition of the insulating film 212 on the top of the oxide semiconductor layers 208_1 and 208_2, many oxygen deficiencies are generated on the top and the side of the oxide semiconductor layers 208_1 and 208_2. Therefore, the oxygen deficiencies formed near the top surface of the oxide semiconductor layers 208_1 and 208_2 are more numerous than the oxygen deficiencies formed near the bottom surface of the oxide semiconductor layers 208_1 and 208_2. In other words, the oxygen deficiencies in the oxide semiconductor layers 208_1 and 208_2 are not uniformly present in the thickness direction of the oxide semiconductor layers 208_1 and 208_2, but are unevenly distributed in the thickness direction of the oxide semiconductor layers 208_1 and 208_2. Specifically, the oxygen deficiencies in the oxide semiconductor layers 208_1 and 208_2 are less on the bottom side of the oxide semiconductor layers 208_1 and 208_2 and more on the top side of the oxide semiconductor layers 208_1 and 208_2.

When an oxygen supply treatment is uniformly applied to the oxide semiconductor layers 208_1 and 208_2 having the above oxygen deficiency distribution, when the amount of oxygen necessary to repair the oxygen deficiencies formed on the top side of the oxide semiconductor layers 208_1 and 208_2 are supplied, the bottom side of the oxide semiconductor layers 208_1 and 208_2 is supplied with an excess amount of oxygen. As a result, defect levels different from oxygen deficiencies are formed on the bottom side due to the excess oxygen. As a result, phenomena such as characteristic fluctuations in reliability tests or a decrease in field effect mobility occur. Therefore, it is necessary to supply oxygen to the upper surface of the oxide semiconductor layers 208_1 and 208_2 to suppress such phenomena while suppressing the oxygen supply to the lower surface of the oxide semiconductor layers 208_1 and 208_2.

The oxidation annealing process is performed with the metal oxide layers 205_1 and 205_2 under the oxide semiconductor layers 208_1 and 208_2 and the metal oxide film 213 on the oxide semiconductor layers 208_1 and 208_2. As a result, the oxygen hammered into the insulating film 212 during the above oxidation annealing process is blocked by the metal oxide film 213, thus preventing its release into the atmosphere. The oxygen released from the insulating film 206 is supplied to the top and side surfaces of the oxide semiconductor layers 208_1 and 208_2. The metal oxide layers 205_1 and 205_2 can suppress the excessive supply of oxygen to the lower portion of the oxide semiconductor layers 208_1 and 208_2. As a result, the oxygen can be efficiently supplied to the oxide semiconductor layers 208_1 and 208_2 to repair oxygen deficiencies.

After oxidation annealing, the metal oxide film 213 is removed. For the subsequent processes, refer to the descriptions in FIG. 9 to FIG. 12.

In the transistors including the oxide semiconductor layers 208_1 and 208_2 produced by the above manufacturing method, in the range where the channel length L of the channel regions 208a and 208f is 2 μm or more and 4 μm or less, and the channel width W of the channel regions 208a and 208f is 2 μm or more and 25 μm or less, mobility of 50 cm²/Vs or more, 55 cm²/Vs or more, or 60 cm²/Vs or more can be obtained for the electrical characteristics.

### Third Modification

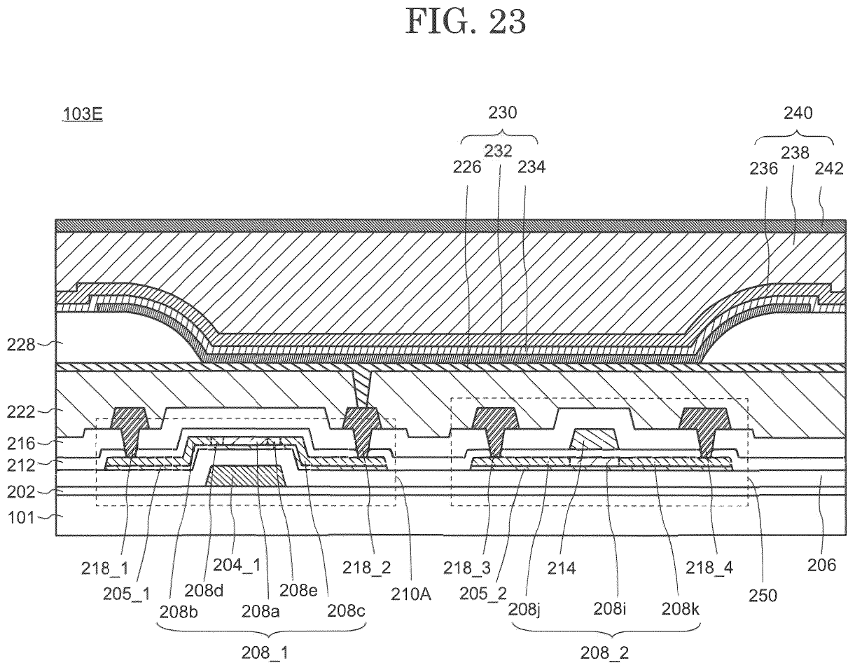

FIG. 23 illustrates a cross-sectional configuration of pixel 103E of the display device 100 according to an embodiment of the invention. The cross-sectional configuration of the pixel 103E of the display device 100 shown in FIG. 23 is similar to that of the pixel 103B shown in FIG. 15, except that the metal oxide layers 205_1 and 205_2 are provided between the insulating film 206 and the oxide semiconductor layers 208_1 and 208_2. For the method of forming the metal oxide layers 205_1 and 205_2 shown in FIG. 23, refer to the descriptions in FIG. 21 and FIG. 22.

In the transistor including the oxide semiconductor layers 208_1 and 208_2 manufactured by the above manufacturing method, the channel length L of the channel regions 208a and 208i is 2 μm or more and 4 μm or less, the channel width W of the channel regions 208a and 208i is 2 μm or more and 25 μm or less, and the mobility of 50 cm²/Vs or more, 55 cm²/Vs or more, or 60 cm²/Vs or more can be obtained for the electrical characteristics.

### Fourth Modification

This embodiment describes a case in which the oxidation annealing process is performed with the metal oxide layers 205_1, 205_2 and the metal oxide film 213 formed. After forming the oxide semiconductor layers 208_1 and 208_2 having the polycrystalline structure described in FIG. 22, the oxidation annealing may be performed with the insulating film 212 deposited and without depositing the metal oxide film 213. In this case, since the pixel structure is the same as that of pixel the 103D shown in FIG. 20 and the pixel 103E shown in FIG. 23, the illustrations in this variation are omitted.

In the display device 100 of this embodiment, the transistor is composed of the oxide semiconductor layers 208_1 and 208_2 having a good polycrystalline structure. In the transistor Tr including the oxide semiconductor layers 208_1 and 208_2, the channel length L of the channel regions 208a and 208i is 2 μm or more and 4 μm or less, the channel width W of the channel regions 208a and 208i is 2 μm or more and 25 μm or less, and the mobility of 30 cm²/Vs or more, 35 cm²/Vs or more, or 40 cm²/Vs or more can be obtained for the electrical characteristics.

### Fourth Embodiment

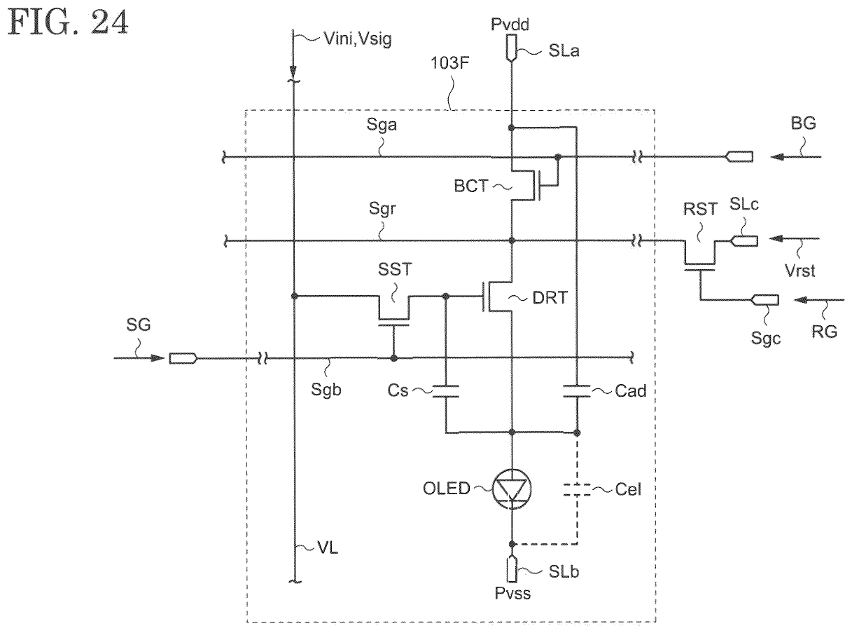

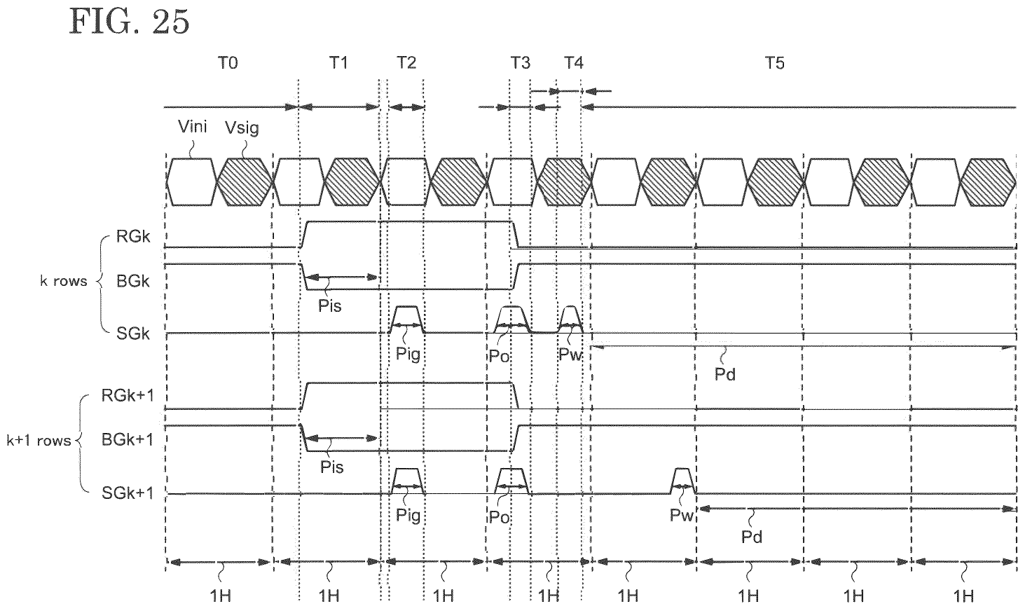

In the present embodiment, the circuit configuration of the pixels included in the display device 100 and operation methods will be described with reference to FIG. 24 and FIG. 25.

### [Equivalent Circuit Diagram]

FIG. 24 is an equivalent circuit diagram of a pixel 103F of the display device 100 according to an embodiment of the present invention. The display device 100 includes the high potential power source line SLa, the low potential power source electrode SLb, a light emission control scanning line Sga, a write control scanning line Sgb, a reset control scanning line Sgc, and the video signal line VL. The high potential power source Pvdd is applied to the high potential power source line SLa, and the low potential power source Pvss is applied to the low potential power source electrode SLb. The light emission control scanning line Sga, the write control scanning line Sgb, and the reset control scanning line Sgc are connected to the gate driving circuits 104_1 and 104_2. In addition, the video signal line VL is connected to the driver IC 105.

The pixel 103F includes the writing transistor SST, the driving transistor DRT, the holding capacity Cs, and an additional capacity Cad. The holding capacity Cs and the additional capacity Cad are capacitors. The additional capacity Cad is an element arranged to adjust the amount of light emission current, and may be unnecessary in some cases. A parasitic capacitance Cel is the capacitance of the light-emitting element itself (parasitic capacitance of the light-emitting element OLED). The light-emitting element OLED also functions as a capacitor.

Each pixel 103F includes an output transistor BCT. In the present embodiment, the four pixels 103F adjacent to each other in the row direction X and the column direction Y share one output transistor BCT. In addition, a plurality of reset transistors RST is arranged in the gate driving circuits 104_1 and 104_2. The reset transistor RST and the reset control scanning line Sgr are connected in a one-to-one manner.

The driving transistor DRT has the structure of the transistor 210 shown in the first embodiment, and the writing transistor SST, the output transistor BCT, and the reset transistor RST have the structure of the transistor 220 shown in the first embodiment. Alternatively, the driving transistor DRT may have the structure of the transistor 210A or the transistor 210B described in the second embodiment, and the writing transistor SST, the output transistor BCT, and the reset transistor RST may have the structure of the transistor 220 or the transistor 250 described in the second embodiment. In the display device 100 according to the present embodiment, all of the driving transistors and the transistors constituting the switches are formed in the same process.

Each of the writing transistor SST, the driving transistor DRT, the output transistor BCT, and the reset transistor RST includes a first terminal, a second terminal, and a control terminal. In the present embodiment, the first terminal is used as a source electrode, the second terminal is used as a drain electrode, and the control terminal is used as a gate electrode.

In the pixel circuit of the pixel, the driving transistor DRT is connected in series with the light-emitting element OLED between the high potential power source line SLa and the low potential power source electrode SLb.

In the output transistor BCT, the drain electrode is connected to the high potential power source line SLa, the source electrode is connected to the drain electrode of the driving transistor DRT, and the gate electrode is connected to the light emission control scanning line Sga. As a result, the output transistor BCT is turned on (conduction state) and off (non-conduction state) by a control signal BG (1 to m/2) from the light emission control scanning line Sga. The output transistor BCT controls the signal BG to control the light emission duration of the light-emitting element OLED.

In the driving transistor DRT, the drain electrode is connected to the source electrode of the output transistor BCT and the reset control scanning line Sgr, and the source electrode is connected to one electrode (in this case, the anode) of the light-emitting element OLED. The other electrode (in this case, the cathode) of the light-emitting element OLED is connected to the low potential power source electrode SLb. The driving transistor DRT outputs a driving current of a current amount corresponding to the video signal Vsig to the light-emitting element OLED.

In the writing transistor SST, the source electrode is connected to the video signal line VL (1 to n), the drain electrode is connected to the gate electrode of the driving transistor DRT, and the gate electrode is connected to the write control scanning line Sgb (1 to m) which functions as a gate wiring for signal write control. The writing transistor SST is turned on/off by the control signal SG (1 to m) supplied from the write control scanning line Sgb. According to the control signal SG (1 to m), the writing transistor SST controls the connection and disconnection between the pixel circuit and the video signal line VL (1 to n), and takes the video signal Vsig from the corresponding video signal line VL (1 to n) into the pixel circuit.

The reset transistor RST is arranged in the gate driving circuits 104_1 and 104_2 for every two rows. The reset transistor RST is connected between the drain electrode of the driving transistor DRT and a reset power source. In the reset transistor RST, the source electrode is connected to a reset power source line SLc connected to the reset power source, the drain electrode is connected to the reset control scanning line Sgr, and the gate electrode is connected to the reset control scanning line Sgc functioning as a gate wiring for reset control. As described above, the reset power source line SLc is connected to the reset power source and is fixed to a reset potential Vrst, which is a constant potential.

The reset transistor RST switches between a conductive state (on) and a non-conductive state (off) between the reset power source line SLc and the reset control scanning line Sgr according to a control signal RG (1 to m/2) supplied through the reset control scanning line Sgc. When the reset transistor RST is switched to the on-state, the potential of the source electrode of the driving transistor DRT is initialized.

The gate driving circuits 104_1 and 104_2 include a shift register, an output buffer, and the like (not shown), and sequentially transfer a horizontal scanning start pulse supplied from the outside to the next stage, and supply three types of control signals: the control signal BG (1 to m/2), the control signal SG (1 to m), and the control signal RG (1 to m/2) to the pixel 103F of each row via the output buffer. In addition, although the control signal RG is not directly supplied to the pixel 103F, a predetermined voltage is supplied from the reset power source line SLc fixed to the reset potential Vrst at a predetermined timing corresponding to the control signal RG. As a result, the light emission control scanning line Sga, the write control scanning line Sgb, and the reset control scanning line Sgc are respectively driven by the control signals BG, SG, and RG.

### [Timing Chart]

FIG. 25 is a timing chart of the gate driving circuits 104_1 and 104_2 for driving the pixels shown in FIG. 24. In FIG. 25, k rows of control signal RGk, control signal BGk, and control signal SGK are shown, and k+1 rows of control signal RGk+1, control signal BGk+1, and control signal SGk+1 are shown. Each section indicated by G1 to G4 is one horizontal period, which continues until the last row, although the rest is omitted. The periods indicated by T0˜ in FIG. 24 will be described in detail below.

### [T0. Previous Frame Light Emission]

The light emission state of a pixel continues in the previous frame until processing in a certain frame period is started.

### [T1. DRT Source Initialization Operation]

In this period, first, the control signal BG is at the L level, the control signal RG is at the H level, and the control signal SG is at the L level, the output transistor BCT is turned off, the reset transistor RST is turned on, and the writing transistor SST is turned off. In this case, the holding capacity Cs holds “a voltage corresponding to the video signal written in the previous frame”. When the video signal Vsig is larger than the reset potential Vrst, the source side also approaches the reset potential Vrst through the driving transistor DRT. In addition, since the reset potential Vrst has approximately the same potential as the low potential power source Pvss, the current supplied to the light-emitting element OLED is stopped. As a result, the potential on the source side of the driving transistor DRT is the lowest in the pixel system.

### [T2. DRT Gate Initialization]

In this period, the control signal BG is at the L level, the control signal RG is at the H level, the control signal SG is at the H level, the video signal line VL is at an initialization potential Vini, the output transistor BCT is turned off, the reset transistor RST is turned on, and the writing transistor SST is turned on. In each pixel 103F in each row, the gate of the driving transistor DRT is fixed to the initialization potential Vini via the writing transistor SST. The initialization potential Vini is set to a potential larger than a threshold value of the driving transistor DRT with respect to the reset potential Vrst. That is, the driving transistor DRT is turned on by this operation. However, since the output transistor BCT is in the off-state, no current yet flows through the driving transistor DRT. In addition, in the T1. DRT source initialization operation, even if the video signal Vsig is not larger than the reset potential Vrst, the source of the driving transistor DRT can also be initialized in this period.

### [T3. Offset Cancel Operation]

In this period, the control signal BG is at the H level, the control signal RG is at the L level, the control signal SG is at the H level, the video signal line VL is at the initialization potential Vini, the output transistor BCT is turned on, the reset transistor RST is turned off, and the writing transistor SST is turned on. Since the driving transistor DRT is turned on by the previous operation, a current is supplied to the driving transistor DRT from the high potential Pvdd through the output transistor BCT. At this stage, no current flows because the voltage between the anode and cathode of the light-emitting element OLED does not exceed the light emission start voltage. Therefore, the source of the driving transistor DRT is charged by the current supplied from the high potential power source Pvdd, and its potential rises. In this case, a gate potential of the driving transistor DRT is Vini, so that the driving transistor DRT is turned off at a stage when the source of the driving transistor DRT is (Vini−Vth), and the increase of the potential is stopped. Vth is a threshold voltage of the driving transistor DRT, and the potential of the source of the driving transistor DRT when the increase of the potential is stopped varies depending on the pixel 103F. That is, according to the present operation, a voltage corresponding to the threshold voltage of the driving transistor DRT is acquired in each pixel 103F. In this case, although a voltage of {(Vini−Vth)−Pvss} is applied between the anode and cathode of the light-emitting element OLED, this voltage does not exceed the light emission start voltage, so no current flows through the light-emitting element OLED.

In addition, according to the timing chart of FIG. 25, although the operations of 1 to 3 are executed in parallel for 2 rows, it is not limited to this. The operations may be performed sequentially for one row, or in parallel for three or more rows.

### [T4. Mobility Cancellation and Video Signal Write Operation]

The control signal BG is at the H level, the control signal RG is at the L level, the control signal SG is at the H level, the video signal line VL is the video signal Vsig, the output transistor BCT is turned on, the reset transistor RST is turned off, and the writing transistor SST is turned on. In each pixel 103F of the row, the video signal Vsig is input to the gate of the driving transistor DRT, and the gate potential of the driving transistor DRT changes from the initialization potential Vini to the video signal Vsig. On the other hand, the source potential of the driving transistor DRT is still (Vini−Vth). As a result, the gate-source voltage of the driving transistor DRT becomes {Vsig−(Vini−Vth)}, which reflects variations in the threshold value between the pixels 103F.

Since the video signal line VL sharing the video signal Vsig is the same in the pixel 103F of a plurality of rows belonging to the same column, the video signal write operation is sequentially performed for each row.

### [T5. Light-Emitting Operation]

The control signal BG is at the H level, the control signal RG is at the L level, the control signal SG is at the L level, the output transistor BCT is turned on, the reset transistor RST is turned off, and the writing transistor SST is turned off. A current is supplied from the high potential power source Pvdd to the driving transistor DRT through the output transistor BCT. The driving transistor DRT supplies a current corresponding to the gate-source voltage set up to the previous stage to the light-emitting element OLED, and the light-emitting element OLED emits light with a brightness corresponding to the current. Since the anode-cathode voltage of the light-emitting element OLED at this time becomes a voltage corresponding to the current, the potential on the anode side rises, but the gate-source voltage of the driving transistor DRT is held by the holding capacity Cs, so that the gate potential of the driving transistor DRT also rises due to the coupling of the holding capacity Cs as the potential on the anode side rises. In practice, the increase of the gate potential of the driving transistor DRT is slightly lower than the potential increase on the anode side because not only the holding capacity Cs but also the additional capacity Cad and other parasitic capacitances are attached to the gate of the driving transistor DRT. However, since this value is known, the potential of the video signal Vsig may be determined so as to have a desired current value at the gate-source voltage of the final driving transistor DRT.

In this way, a series of operations of the pixel is completed. When the operation is completed from the first row to the last row, one picture is displayed within one frame period. Thereafter, the operation is repeated to display an image.

Any one of the bottom-gate driving transistors 210, 210A, and 210B described in the first embodiment, the first modification and the second embodiment, and the second modification is applied to the driving transistor DRT. In addition, any of the top gate-driving transistors 220 and 250 described in the first embodiment and the second embodiment can be applied to the writing transistor SST, the reset transistor RST, and an initialization transistor IST, and the like. As a result, since the S value of the driving transistor DRT is large, the change in the current of the driving transistor DRT can be reduced in the low gradation region that needs to be controlled with a small current, and the gradation can be finely controlled. As a result, it is possible to suppress display unevenness in the display region 102.

### Fifth Embodiment

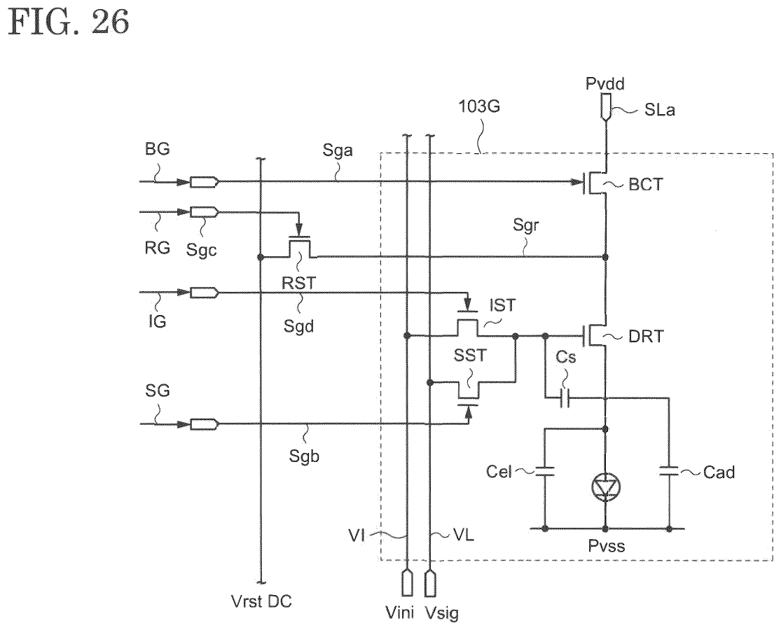

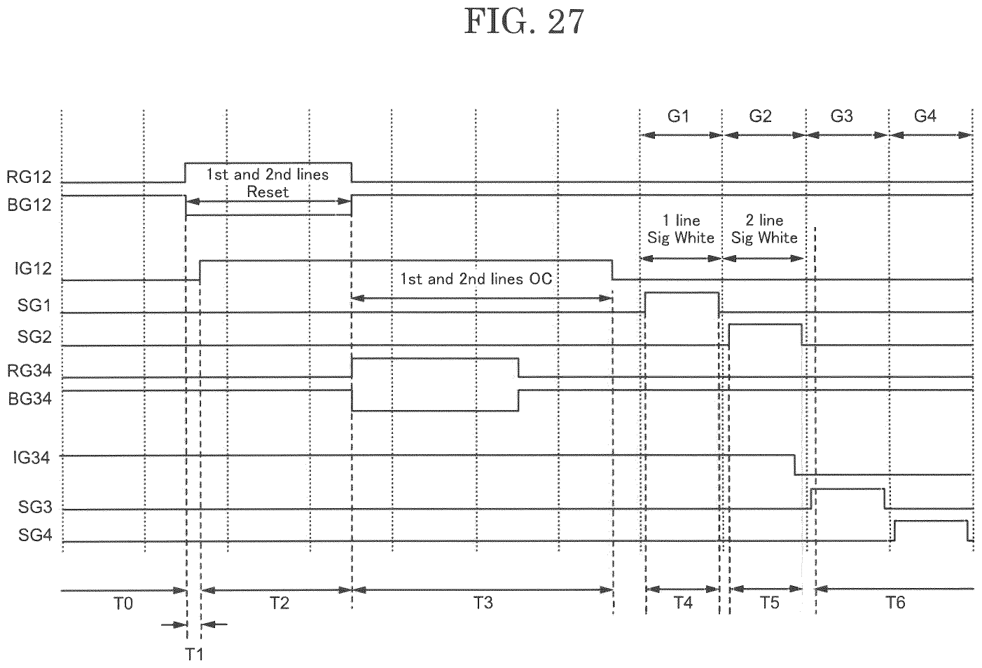

In the present embodiment, the circuit configuration of a pixel 103G included in the display device 100 and operation methods will be described with reference to FIG. 26 and FIG. 27.

### [Circuit Diagram]

FIG. 26 is an equivalent circuit diagram of the pixel circuit of the pixel 103G. The light emission control scanning line Sga, the write control scanning line Sgb, the reset control scanning line Sgc, and an initialization control scanning line Sgd are connected to the gate driving circuits 104_1 and 104_2 arranged on the outer side of the display region 102, respectively. The output transistor BCT, the initialization transistor IST, the writing transistor SST, and the driving transistor DRT are arranged in each pixel 103G. Some transistors may be shared between the plurality of adjacent pixels 103G. The reset transistor RST is arranged on the outer side of the display region, for example, one in each row. The holding capacity Cs may be arranged between the gate-source of the driving transistor DRT. The parasitic capacitance Cel is the parasitic capacitance between the anode-cathode of the light-emitting element OLED. The high potential power source Pvdd is applied to the anode of the light-emitting element OLED via the output transistor BCT and the driving transistor DRT, and the low potential power source Pvss is applied to the cathode. The output transistor BCT, the initialization transistor IST, and the writing transistor SST function as switching elements that select conduction and non-conduction between two nodes, and the driving transistor DRT functions as a current control element that controls the current flowing through the OLED according to the gate-source voltage. In the present embodiment, the transistor 210 is applied as the driving transistor DRT, and the structure of the transistor 220 is applied as the output transistor BCT, the initialization transistor IST, and the writing transistor SST.

### [Timing Chart]

FIG. 27 is a timing chart of the gate driving circuits 104_1 and 104_2 for driving the pixels shown in FIG. 26. Each section indicated by G1 to G3 is one horizontal period, which continues until the last row. The period indicated by T0 to T6 in FIG. 27 will be described below.

### [T0. Previous Frame Light Emission]

The light emission state of the pixel continues in the previous frame until processing in a certain frame period is started.

### [T1. Source Initialization Operation of Driving Transistor DRT]

In this period, first, the control signal BG is at the L level, the control signal RG is at the H level, a control signal IG is at the L level, the control signal SG is at the L level, the output transistor BCT is turned off, the reset transistor RST is turned on, the initialization transistor IST is turned off, and the writing transistor SST is turned off. In this case, the holding capacity Cs holds “a voltage corresponding to the video signal written in the previous frame”. When the video signal Vsig is larger than the reset potential Vrst, the source side also approaches the reset potential Vrst through the driving transistor DRT. In addition, since the reset potential Vrst has approximately the same potential as the low potential power source Pvss, the current supplied to the light-emitting element OLED is stopped. As a result, the potential of the driving transistor DRT is the lowest in the pixel system.

### [T2. Gate Initialization of Driving Transistor DRT]

The control signal IG is at the H level and the initialization transistor IST is turned on. In each pixel of the row, the gate of the driving transistor DRT is fixed to the initialization potential Vini via the initialization transistor IST. The initialization potential Vini is set to a potential larger than a threshold value of the driving transistor DRT with respect to the reset potential Vrst. That is, the driving transistor DRT is turned on by this operation. However, since the output transistor BCT is in the off-state, no current yet flows through the driving transistor DRT.

### [T3. Offset Cancel Operation]

The control signal BG is at the H level, the control signal RG is at the L level, the control signal IG is at the H level, the output transistor BCT is turned on, the reset transistor RST is turned off, and the initialization transistor IST is turned on. Since the driving transistor DRT is turned on by the previous operation, a current is supplied to the driving transistor DRT from the Pvdd through the output transistor BCT. At this stage, no current flows because the voltage between the anode and cathode of the light-emitting element OLED does not exceed the light emission start voltage. Therefore, the source of the driving transistor DRT is changed by the current supplied from the high potential power source Pvdd, and its potential rises. In this case, the gate potential of the driving transistor DRT is the initialization potential Vini, so that the driving transistor DRT is turned off at a stage when the source of the driving transistor DRT is (Vini−Vth), and the increase of the potential is stopped. Vth is a threshold voltage of the driving transistor DRT and varies depending on the pixel 103G, so that the potential of the source of the DRT when the increase of the potential is stopped varies depending on the pixel. That is, according to the present operation, a voltage corresponding to the threshold voltage of the driving transistor DRT is acquired in each pixel. In this case, although a voltage of {(Vini−Vth)−Pvss} is applied between the anode and cathode of the light-emitting element OLED, this voltage does not exceed the light emission start voltage, so no current flows through the light-emitting element OLED.

In addition, according to the timing chart of FIG. 27, although the operations of T1 to T3 are executed in parallel for 2 rows, it is not limited to this. The operations may be performed sequentially for one row, or in parallel for three or more rows.

### [T4. T5. Video Signal Write Operation]

The control signal BG is at the H level, the control signal RG is at the L level, the control signal IG is at the L level, the control signal SG is at the H level, the output transistor BCT is turned on, the reset transistor RST is turned off, the initialization transistor IST is turned off, and the writing transistor SST is turned on. In each pixel of the row, the video signal Vsig is input to the gate of the driving transistor DRT, and the gate potential of the driving transistor DRT changes from Vini to Vsig. On the other hand, the source potential of the driving transistor DRT is still (Vini−Vth). As a result, the gate-source voltage of the driving transistor DRT becomes {Vsig−(Vini−Vth)}, which reflects variations in the threshold value between the pixels.

Since the video signal line VL sharing Vsig is the same in the pixel of a plurality of rows belonging to the same column, the write operation of the video signal Vsig is sequentially performed for each row.

### [T6. Light-Emitting Operation]

The control signal BG is at the H level, the control signal RG is at the L level, the control signal IG is at the L level, the control signal SG is at the L level, the output transistor BCT is turned on, the reset transistor RST is turned off, the initialization transistor IST is turned off, and the writing transistor SST is turned off. A current is supplied from the high potential power source Pvdd to the driving transistor DRT through the output transistor BCT. The driving transistor DRT supplies a current corresponding to the gate-source voltage set up to the previous stage to the light-emitting element OLED, and the light-emitting element OLED emits light with a brightness corresponding to the current. Since the anode-cathode voltage of the light-emitting element OLED at this time becomes a voltage corresponding to the current, the potential on the anode side rises, but the gate-source voltage of the driving transistor DRT is held by the holding capacity Cs, so that the gate potential of the driving transistor DRT also rises due to the coupling of the holding capacity Cs as the potential on the anode side rises. In practice, the increase of the gate potential of the driving transistor DRT is slightly lower than the potential increase on the anode side since not only the holding capacity Cs but also the additional capacity Cad and other parasitic capacitance Cel are attached to the gate of the driving transistor DRT. However, since this value is known, the potential of the video signal Vsig may be determined so as to have a desired current value at the gate-source voltage of the final driving transistor DRT.

In this way, a series of operations of the pixel 103G is completed. When the operation is completed from the first row to the last row, one picture is displayed within one frame period. Thereafter, the operation is repeated to display an image.

Any one of the bottom-gate driving transistors 210, 210A, and 210B described in the first embodiment and the second embodiment is applied to the driving transistor DRT. In addition, any of the top gate-driving transistors 220 and 250 described in the first embodiment and the second embodiment is applied to the writing transistor SST, and the reset transistor RST, the initialization transistor IST, and the like. As a result, since the S value of the driving transistor DRT is large, the change in the current of the driving transistor DRT can be reduced in the low gradation region that needs to be controlled with a small current, and the gradation can be finely controlled. As a result, it is possible to suppress display unevenness in the display region 102.

The addition, deletion, or design change of components, or the addition, deletion, or condition change of processes as appropriate by those skilled in the art based on a display device exemplified by the embodiments and examples of the present invention are also included in the scope of the present invention as long as they are provided with the gist of the present invention. Furthermore, each of the embodiments described above can be appropriately combined and implemented as long as no contradiction is caused.

It is understood that, even if the effect is different from those provided by each of the above-described embodiments, the effect obvious from the description in the specification or easily predicted by persons ordinarily skilled in the art is apparently derived from the present invention.

Within the spirit of the present invention, it is understood that various modifications and changes can be made by those skilled in the art and that these modifications and changes also fall within the scope of the present invention. For example, the addition, deletion, or design change of components, or the addition, deletion, or condition change of processes as appropriate by those skilled in the art based on each embodiment are also included in the scope of the present invention as long as they are provided with the gist of the present invention.

What is claimed is:

1. A display device comprising:
a light-emitting element;
a first transistor controlling a current value flowing from a driving power supply line to the light-emitting element; and
a second transistor applying a voltage corresponding to a luminance of the light-emitting element to a first gate electrode of the first transistor,
the first transistor including:
the first gate electrode;
a first insulating film provided on the first gate electrode;
a first oxide semiconductor layer provided on the first insulating film, and having a region overlapping the first gate electrode;
a second insulating film provided on the first oxide semiconductor layer; and
a first conductive layer provided on the second insulating film, the second transistor including:
the first insulating film;
a second oxide semiconductor layer provided on the first insulating film;
a second insulating film arranged on the first oxide semiconductor layer and the second oxide semiconductor layer and having a thickness smaller than a thickness of the first insulating film; and
a second gate electrode arranged on the second insulating film, and having a region overlapping the second oxide semiconductor layer,
wherein
the first oxide semiconductor layer has a first channel region and a first high concentration impurity region sandwiching the first channel region,
the second semiconductor layer has a second channel region and a second high concentration impurity region sandwiching the second channel region,
the first conductive layer is electrically connected to the light emitting element, and
an etching rate of the first oxide semiconductor layer and the second semiconductor layer is less than 3 nm/min when the first oxide semiconductor layer and the second semiconductor layer are etched using an etching solution containing phosphoric acid as a main component at 40° C.

2. The display device according to claim 1, wherein
a thickness of the first insulating film is 100 nm or more and 500 nm or less, and
a thickness of the second insulating film is 30 nm or more and 150 nm or less.

3. The display device according to claim 1, wherein
an impurity element in the first high concentration impurity region and an impurity element in the second high concentration impurity region are the same element, and
a concentration of the impurity element in the first high concentration impurity region and the second high concentration impurity region is 1×10¹⁸ cm⁻³ or more and 1×10²¹ cm⁻³ or less as measured by SIMS analysis.

4. The display device according to claim 3, wherein
a sheet resistance in the first high concentration impurity region and the second high concentration impurity region is 1000 Ω/sq. or less.

5. The display device according to claim 1, further comprising:
a first metal oxide layer provided between the first insulating film and the first oxide semiconductor layer; and
a second metal oxide layer provided between the first insulating film and the second oxide semiconductor layer,
wherein
a thickness of the first metal oxide layer and a thickness of the second metal oxide layer are 1 nm or more and 10 nm or less.

6. The display device according to claim 1, wherein
the etching solution includes nitric acid and acetic acid.

7. The display device according to claim 1, wherein
an etching rate is less than 5 nm/min when the first oxide semiconductor layer and the second oxide semiconductor layer are etched using 0.5% of a hydrofluoric acid solution at room temperature.

8. The display device according to claim 1, wherein
the first oxide semiconductor layer and the second oxide semiconductor layer are formed by a heat treatment of an oxide semiconductor film having an amorphous structure, and
an etching rate is 100 nm/min or more when the oxide semiconductor is etched using the etching solution at 40° C.

9. The display device according to claim 1, wherein
the first oxide semiconductor layer and the second oxide semiconductor layer include a plurality of metallic elements,
one of the plurality of metallic elements is indium, and
the atomic ratio of indium to the plurality of metal elements is 50% or more.

10. A display device comprising:
a light-emitting element;
a first transistor controlling a current value flowing from a driving power supply line to the light-emitting element; and
a second transistor applying a voltage corresponding a luminance of the light-emitting element to a first gate electrode of the first transistor,
the first transistor including:
the first gate electrode;
a first insulating film provided on the first gate electrode; and
a first oxide semiconductor layer provided on the first insulating film, and having a region overlapping the first gate electrode;
the second transistor including:
the first insulating film;
a second oxide semiconductor layer provided on the first insulating film;
a second insulating film arranged on the first oxide semiconductor layer and the second oxide semiconductor layer and having a thickness smaller than a thickness of the first insulating film; and
a second gate electrode arranged on the second insulating film, and having a region overlapping the second oxide semiconductor layer,
wherein
the first oxide semiconductor layer has a first channel region, a low concentration impurity region sandwiching the first channel region, and a first high concentration impurity region adjacent to the low concentration impurity region,
the second semiconductor layer has a second channel region and a second high concentration impurity region sandwiching the second channel region, and
an etching rate of the first oxide semiconductor layer and the second semiconductor layer is less than 3 nm/min when the first oxide semiconductor layer and the second semiconductor layer are etched using an etching solution containing phosphoric acid as a main component at 40° C.

11. The display device according to claim 10, wherein
a low concentration impurity region overlaps the first gate electrode.

12. The display device according to claim 10, wherein
a thickness of the first insulating film is 100 nm or more and 500 nm or less, and
a thickness of the second insulating film is 30 nm or more and 150 nm or less.

13. The display device according to claim 10, wherein
an impurity element in the first high concentration impurity region and an impurity element in the second high concentration impurity region are the same element.

14. The display device according to claim 10, wherein
a concentration of the impurity element in the first high concentration impurity region and the second high concentration impurity region is 1×10¹⁸ cm⁻³ or more and 1×10²¹ cm⁻³ or less as measured by SIMS analysis, and
a concentration of the impurity element in the low concentration impurity region is less than 1×10¹⁸ cm⁻³ as measured by SIMS analysis.

15. The display device according to claim 14, wherein
a sheet resistance in the first high concentration impurity region and the second high concentration impurity region is 1000 Ω/sq. or less.

16. The display device according to claim 10, further comprising
a first metal oxide layer provided between the first insulating film and the first oxide semiconductor layer; and
a second metal oxide layer provided between the first insulating film and the second oxide semiconductor layer,
wherein
a thickness of the first metal oxide layer and a thickness of the second metal oxide layer are 1 nm or more and 10 nm or less.

17. The display device according to claim 10, wherein
the etching solution includes nitric acid and acetic acid.

18. The display device according to claim 10, wherein
an etching rate is less than 5 nm/min when the first oxide semiconductor layer and the second oxide semiconductor layer are etched using 0.5% of a hydrofluoric acid solution at room temperature.

19. The display device according to claim 10, wherein
the first oxide semiconductor layer and the second oxide semiconductor layer are formed by a heat treatment of an oxide semiconductor film having an amorphous structure, and
an etching rate is less than 100 nm/min when the oxide semiconductor is etched using the etching solution at 40° C.

20. The display device according to claim 10, wherein
the first oxide semiconductor layer and the second oxide semiconductor layer include a plurality of metallic elements,
one of the plurality of metallic elements is indium, and
the atomic ratio of indium to the plurality of metal elements is 50% or more.
